(19) United States
(12) Patent Application Publication
(10) Pub. No.: US 2009/0230460 A1
(43) Pub. Date: Sep. 17, 2009

(54) NONVOLATILE SEMICONDUCTOR MEMORY

(76) Inventor: Toshitake YAEGASHI, Yokohama-shi (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 12/400,435

(22) Filed: Mar. 9, 2009

(30) Foreign Application Priority Data
Mar. 12, 2008 (JP) 2008-062938

(51) Int. Cl. H01L 29/792

(52) U.S. Cl. 257/324; 257/E29.309

(57) ABSTRACT

A nonvolatile semiconductor memory of an aspect of the present invention including a memory cell which has a first gate insulating film, a charge storage layer, a block insulating film, and a first gate electrode on the block insulating film, a first transistor which has a second gate insulating film and a second gate electrode, a second transistor which has a third gate insulating film and a third gate electrode, and a third transistor which has a fourth gate insulating film and a fourth gate electrode and which is different in drive voltage from the second transistor, wherein the second gate insulating film includes an insulating film of the same configuration as the block insulating film, the second gate electrode has the same structure as the first gate electrode, and the third and fourth gate electrodes partly include conductive layers of the same configuration as the first gate electrode.

### CROSS-REFERENCE TO RELATED APPLICATIONS

This application is based upon and claims the benefit of priority from prior Japanese Patent Application No. 2008-062938, filed Mar. 12, 2008, the entire contents of which are incorporated herein by reference.

### BACKGROUND OF THE INVENTION

1. Field of the Invention

The present invention relates to a nonvolatile semiconductor memory, and more particularly, it relates to a flash memory.

2. Description of the Related Art

Nonvolatile semiconductor memories such as flash memories are installed in various electronic devices. Recently, a flash memory using metal-oxide-nitride-oxide-semiconductor (MONOS) type memory cells has been reported (e.g., see Jpn. Pat. Appln. KOKAI Publication No. 2004-296683).

In the flash memory, a select transistor is formed simultaneously with the memory cell and therefore has the same gate structure as the memory cell. In this structure, the select transistor also includes a charge storage layer. Thus, if more than one writings/readings are performed in the flash memory, a charge is injected into the charge storage layer of the select transistor due to a voltage applied to a gate electrode of the select transistor in operation. This changes the threshold voltage of the select transistor and causes wrong operation of the flash memory.

In order to improve this problem, the gate structure of the memory cell has to be different from the gate structure of the select transistor. In this case, the memory cell and the select transistor are formed in different manufacturing processes, so that the manufacturing process of the whole flash memory is increased, and the manufacturing cost of the flash memory is increased.

In that case, simultaneous gate fabrication using a common process is difficult due to the difference of the gate structure between the memory cell and the select transistor. Therefore, the distance between the memory cell and the select transistor needs to be increased to ensure an enough process margin for fabrication so that the gate fabrication may be performed in difference processes. This leads to an increased chip area in the flash memory and further to an increased manufacturing cost.

Moreover, in a peripheral circuit formed on the same chip (wafer) as the memory cell and the select transistor, gate electrodes of peripheral transistors constituting the peripheral circuit may be formed of a material different from that of the gate structures of the memory cell and the select transistor. In this case, there is a problem of a further increase in the manufacturing cost due to increased manufacturing processes because a gate forming process for the peripheral transistor has to be different from that for the memory cell and the select transistor.

### BRIEF SUMMARY OF THE INVENTION

A nonvolatile semiconductor memory of an aspect of the present invention comprising: a semiconductor substrate; a memory cell array region provided in the semiconductor substrate; a peripheral circuit region provided in the semiconductor substrate adjacently to the memory cell array region; at least one memory cell which is provided in the memory cell array region and which has a first gate insulating film on the surface of the semiconductor substrate, a charge storage layer on the first gate insulating film, a block insulating film on the charge storage layer, and a first gate electrode on the block insulating film; at least one first transistor which is provided in the memory cell array region and which has a second gate insulating film on the surface of the semiconductor substrate and a second gate electrode on the second gate insulating film; at least one second transistor which is provided in the peripheral circuit region and which has a third gate insulating film on the surface of the semiconductor substrate and a third gate electrode on the third gate insulating film; and at least one third transistor which is provided in the peripheral circuit region and which has a fourth gate insulating film on the surface of the semiconductor substrate and a fourth gate electrode on the fourth gate insulating film and which is different in drive voltage from the second transistor, wherein the second gate insulating film includes an insulating film of the same configuration as the block insulating film, the second gate electrode has the same structure as the first gate electrode, and the third and fourth gate electrodes partly include conductive layers of the same configuration as the first gate electrode.

A nonvolatile semiconductor memory of an aspect of the present invention comprising: a semiconductor substrate; a memory cell array region provided in the semiconductor substrate; a peripheral circuit region provided in the semiconductor substrate adjacently to the memory cell array region; at least one memory cell which is provided in the memory cell array region and which has a first gate insulating film on the surface of the semiconductor substrate, a charge storage layer on the first gate insulating film, a block insulating film on the charge storage layer, and a first gate electrode on the block insulating film; at least one first transistor which is provided in the memory cell array region and which has a second gate insulating film on the surface of the semiconductor substrate and a second gate electrode on the second gate insulating film; at least one second transistor which is provided in the peripheral circuit region and which has a third gate insulating film on the surface of the semiconductor substrate and a third gate electrode on the third gate insulating film; and at least one third transistor which is provided in the peripheral circuit region and which has a fourth gate insulating film on the surface of the semiconductor substrate and a fourth gate electrode on the fourth gate insulating film and which is different in drive voltage from the second transistor, wherein the first gate electrode has a plurality of conductive layers, the second gate insulating film includes an insulating film of the same configuration as the block insulating film, the second gate electrode has the same structure as the first gate electrode, and the third and fourth gate electrodes include conductive layers of the same configuration as at least one of the plurality of conductive layers constituting the first gate electrode.

A nonvolatile semiconductor memory of an aspect of the present invention comprising: a semiconductor substrate; a memory cell array region provided in the semiconductor substrate; a peripheral circuit region provided in the semiconductor substrate adjacently to the memory cell array region; at least one memory cell which is provided in the memory cell array region and which has a first gate insulating film on the surface of the semiconductor substrate, a charge storage layer on the first gate insulating film, a block insulating film on the charge storage layer, and a first gate electrode on the block insulating film; at least one first transistor which is provided in the memory cell array region and which has a second gate insulating film on the surface of the semiconductor substrate and a second gate electrode on the second gate insulating film; at least one second transistor which is provided in the peripheral circuit region and which has a third gate insulating film on the surface of the semiconductor substrate and a third gate electrode on the third gate insulating film; and at least one third transistor which is provided in the peripheral circuit region and which has a fourth gate insulating film on the surface of the semiconductor substrate and a fourth gate electrode on the fourth gate insulating film and which is different in drive voltage from the second transistor, wherein the second and third gate insulating films include insulating films of the same configuration as the block insulating film, and the second and third gate electrodes have the same structure as the first gate electrode.

### BRIEF DESCRIPTION OF THE SEVERAL VIEWS OF THE DRAWING

FIG. 1 is a schematic diagram showing the overall configuration of a flash memory;

FIG. 2 is a diagram showing the planar structure of the flash memory;

FIG. 3 is a sectional view showing the structure of a flash memory according to a first embodiment;

FIG. 4 is a sectional view showing the structure of the flash memory according to the first embodiment;

FIG. 5 is a diagram showing one step of manufacturing the flash memory according to the first embodiment;

FIG. 6 is a diagram showing one step of manufacturing the flash memory according to the first embodiment;

FIG. 7 is a diagram showing one step of manufacturing the flash memory according to the first embodiment;

FIG. 8 is a diagram showing one step of manufacturing the flash memory according to the first embodiment;

FIG. 9 is a diagram showing one step of manufacturing the flash memory according to the first embodiment;

FIG. 10 is a diagram showing one step of manufacturing the flash memory according to the first embodiment;

FIG. 11 is a diagram showing one step of manufacturing the flash memory according to the first embodiment;

FIG. 12 is a sectional view showing a first modification of the flash memory according to the first embodiment;

FIG. 13 is a sectional view showing a second modification of the flash memory according to the first embodiment;

FIG. 14 is a sectional view showing the structure of a flash memory according to a second embodiment;

FIG. 15 is a sectional view showing the structure of a flash memory according to a third embodiment;

FIG. 16 is a sectional view showing the structure of the flash memory according to the third embodiment;

FIG. 17 is a sectional view showing the structure of the flash memory according to the third embodiment;

FIG. 18 is a sectional view showing the structure of a flash memory according to a fourth embodiment; and

FIG. 19 is an equivalent circuit diagram showing an application of the embodiments of the present invention.

### DETAILED DESCRIPTION OF THE INVENTION

Hereinafter, a plurality of embodiments of the present invention will be described in detail with reference to the drawings.

### 1. OUTLINE

The embodiments of the present invention concern a nonvolatile semiconductor memory, in particular, a flash memory.

In the flash memory of the present embodiments, a memory cell has, for example, a MONOS type gate structure.

A select transistor and a peripheral transistor (low- or high-breakdown-voltage MIS transistors) provided on the same chip as the memory cell have gate structures which include no insulating films of the same configuration as a charge storage layer of the memory cell. Moreover, the gate structures of the select transistor and the peripheral transistor include, in parts of their gate insulating films, insulating films of the same configuration as a block insulating film of the memory cell, and include, in parts of their gate electrodes, conductive layers of the same configuration as a gate electrode of the memory cell.

According to this structure, the select transistor and the peripheral transistor are MIS transistors, so that there is no variation of a threshold voltage even if a voltage is applied to the gate electrode during the operation of the flash memory. Thus, according to the embodiments of the present invention, wrong operation of the flash memory can be prevented.

Furthermore, according to the above-described structure, the difference of gate structure between the memory cell and the select and peripheral transistors results from the presence of the thin charge storage layer (e.g., about 5 nm thick). Therefore, the conductive layers and insulating films included in stacks constituting gates have about the same configuration, which facilitates gate fabrication in a manufacturing process. Consequently, according to the embodiments of the present invention, the manufacturing cost of the flash memory can be reduced.

### 2. EMBODIMENTS

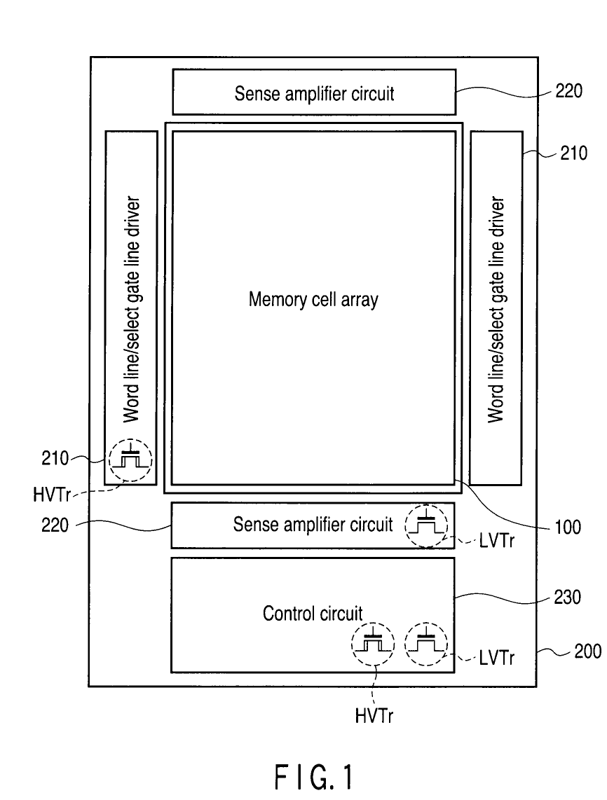

A nonvolatile semiconductor memory according to each of the embodiments of the present invention will be described below with reference to FIGS. 1 to 18. A flash memory is described below by way of example in each of the embodiments.

### (1) First Embodiment

A flash memory according to a first embodiment of the present invention will be described below with FIGS. 1 to 13.

(a) Configuration

The configuration of the nonvolatile semiconductor memory according to the embodiment of the present invention will be described below with FIG. 1. In the present embodiment, a flash memory is described as an example of the nonvolatile semiconductor memory.

FIG. 1 is a schematic diagram showing the configuration of the flash memory. As shown in FIG. 1, the flash memory mainly comprises a memory cell array region 100 and a peripheral circuit region 200 therearound. These regions are provided on the same chip (semiconductor substrate).

At least one memory cell and at least one select transistor are provided in the memory cell array region 100. The memory cell functions as a storage element, and the select transistor functions as a switch element for the memory cell selected for data writing/reading.

Hereinafter, out of the memory cell array region 100, a region where the memory cell is formed (disposed) is called a memory cell formation region, while a region where the select transistor is formed (disposed) is called a select transistor formation region. The memory cell formation region and the select transistor formation region are disposed adjacently in the memory cell array region 100.

Furthermore, a word line/select gate line driver 210, a sense amplifier circuit 220 and a control circuit 230 are provided in the peripheral circuit region 200. These circuits 210, 220, 230 have a plurality of low-breakdown-voltage MIS transistors and a plurality of high-breakdown-voltage MIS transistors as peripheral transistors.

Hereinafter, out of the peripheral circuit region 200, a region where the low-breakdown-voltage MIS transistors are formed (disposed) is called a low-breakdown-voltage region, and a region where the high-breakdown-voltage MIS transistors are formed (disposed) is called a high-breakdown-voltage region.

The low-breakdown-voltage MIS transistors are used for, for example, elements to constitute the sense amplifier circuit 220. The high-breakdown-voltage MIS transistors are used for, for example, transfer gates in the word line/select gate line driver 210.

Hereinafter, one memory cell and one select transistor are shown and their structures are described in the embodiments of the present invention. For the peripheral transistors as well, one low-breakdown-voltage MIS transistor and one high-breakdown-voltage MIS transistor are shown and their structures are described.

(b) Structure

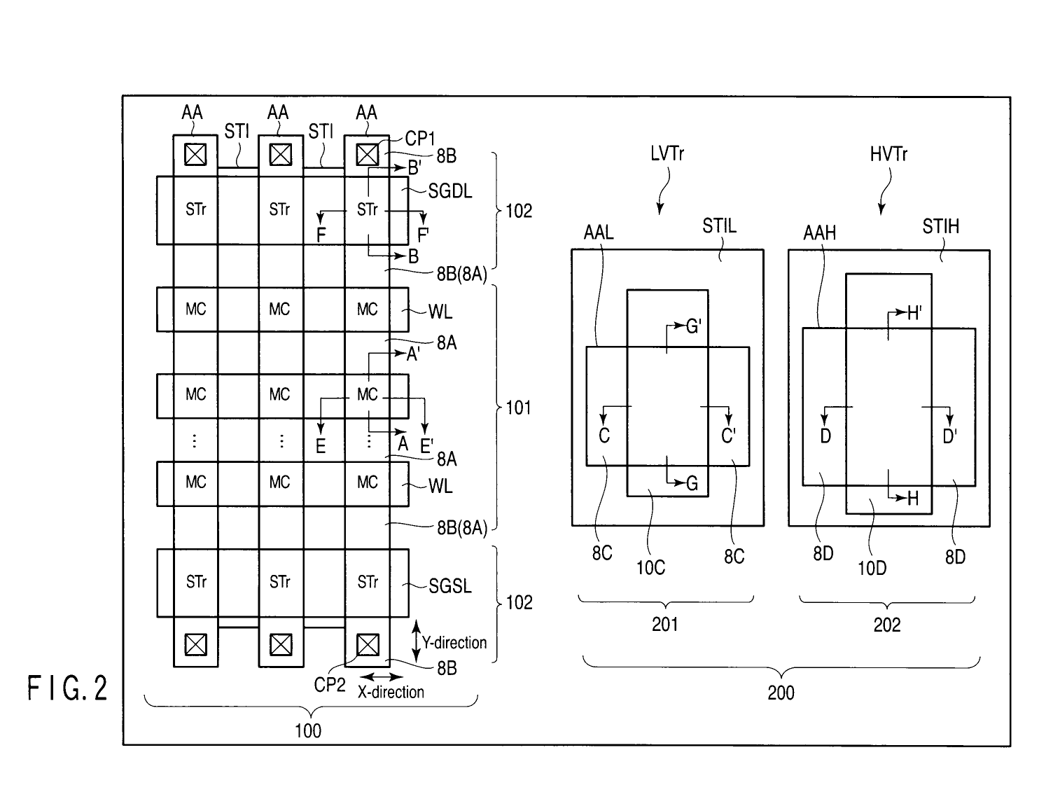

The structures of a memory cell MC, a select transistor ST, a low-breakdown-voltage MIS transistor LVTr and a high-breakdown-voltage MIS transistor HVTr according to the first embodiment of the present invention will be described with FIGS. 2 to 4.

FIG. 2 shows the planar structures of the memory cell array region 100 and the peripheral circuit region 200. As shown in FIG. 2, the memory cell array region 100 comprises a plurality of element regions AA and a plurality of isolation regions STI. The element regions AA each have a striped shape extending in a Y-direction, and are provided along an X-direction perpendicular to the Y-direction. One isolation region STI is provided between adjacent two element regions AA, and the adjacent element regions AA are electrically separated by this isolation region STI.

Word lines WL and select gate lines SGDL, SGSL extend in the X-direction across the plurality of element regions AA. The memory cells MC are provided in regions where the word lines WL and the element regions AA cross each other. Select transistors STr are provided in regions where the select gate lines SGDL, SGSL and the element regions AA cross each other. In the element regions AA between the word lines WL adjacent in the Y-direction, between the adjacent select gate lines and between the word lines WL and the select gate lines SGDL, SGSL, impurity diffusion layers 8A, 8B are formed which serve as source regions or drain regions of the memory cells MC and the select transistors STr.

One of the two impurity diffusion layers serving as the source/drain regions 8B of the select transistor STr is shared with the memory cell MC, and the other is connected with a contact plug CP1, CP2 provided on its surface. The contact plug CP1 provided on the other impurity region 8B of the select transistor STr provided on a drain side (the side of the select gate line SGDL) is connected with a striped bit line (not shown) extending in the Y-direction. The contact plug CP2 provided on the other impurity region 8B of the select transistor STr provided on a source side (the side of the select gate line SGSL) is connected with a source line (not shown).

FIG. 2 also shows the planar structure of the peripheral circuit region 200. A low-breakdown-voltage region 201 comprises an isolation region STIL, and an element region AAL enclosed by the isolation region STIL. A gate electrode 10C of the low-breakdown-voltage MIS transistor is provided on the element region AAL in such a manner as to divide the element region AAL. In the element region AAL, two impurity diffusion layers 8C serving as source/drain regions are provided in such a manner as to interpose the gate electrode 10C therebetween.

A high-breakdown-voltage region 202 comprises an isolation region STIH, and an element region AAH enclosed by the isolation region STIH. A gate electrode 10D of the high-breakdown-voltage MIS transistor is provided on the element region AAH in such a manner as to divide the element region AAH. In the element region AAH, two impurity diffusion layers 8D serving as source/drain regions are provided in such a manner as to interpose the gate electrode 10D therebetween.

In the low-breakdown-voltage/high-breakdown-voltage MIS transistors LVTr, HVTr, contact plugs (not shown) are provided on the impurity diffusion layers 8C, 8D and on the gate electrodes 10C, 10D. The contact plugs are connected to interconnect lines (not shown) provided in an upper layer, such that the potentials of the impurity diffusion layers 8C, 8D and the gate electrodes 10C, 10D are controlled.

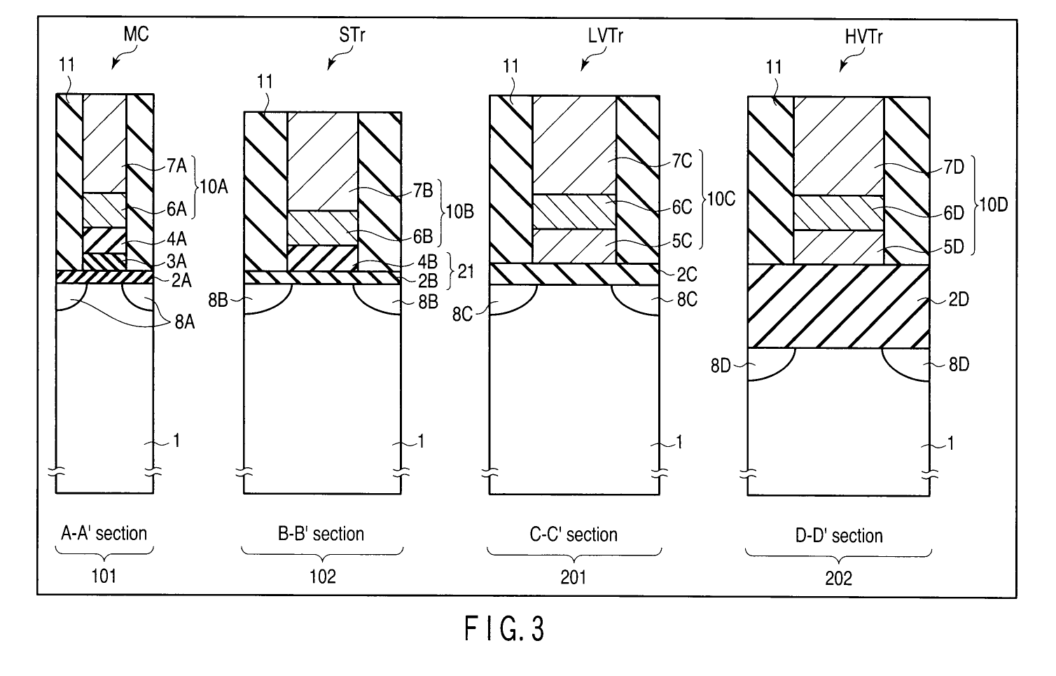

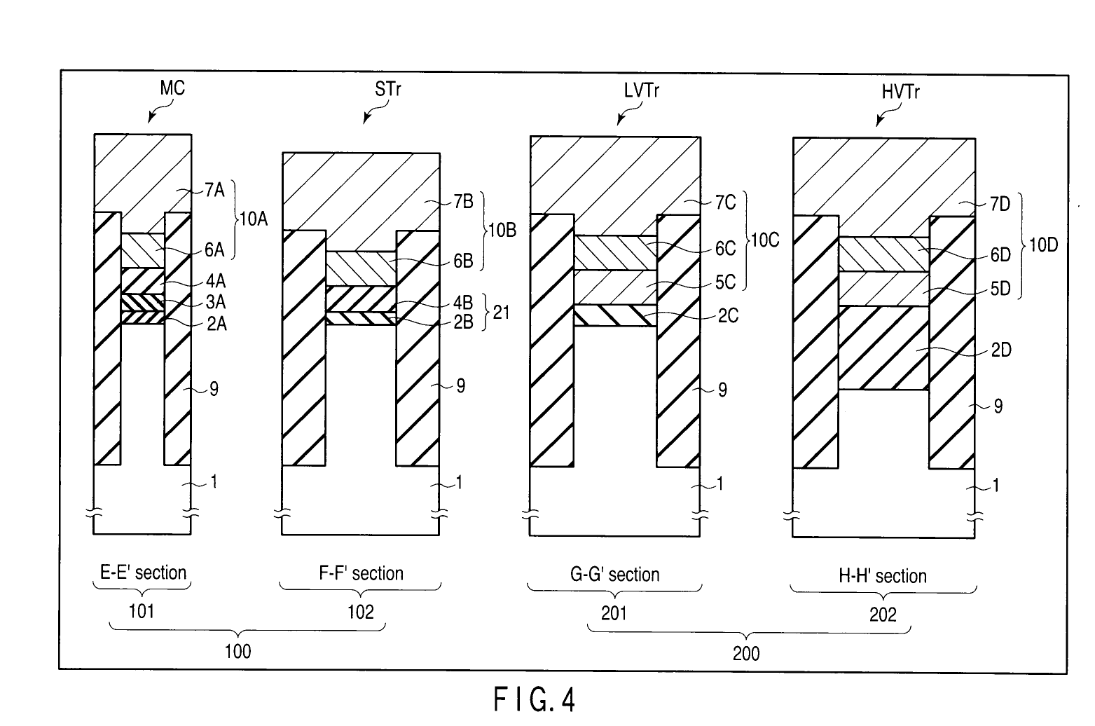

FIG. 3 shows sectional structures along the line A-A′ and the line B-B′ in the memory cell array region 100 in FIG. 2, and sectional structures along the line C-C′ and the line D-D′ in the peripheral circuit region 200 in FIG. 2. The sectional structures shown in FIG. 3 correspond to the sectional structures of the elements in a channel length direction. Further, FIG. 4 shows sectional structures along the line E-E′ and the line F-F′ in the memory cell array region 100 in FIG. 2, and sectional structures along the line G-G′ and the line H-H′ in the peripheral circuit region 200 in FIG. 2. The sectional structures shown in FIG. 4 correspond to the sectional structures of the elements in a channel width direction.

As shown in FIG. 3, the memory cell MC is an element of a MONOS structure, and is disposed in a memory cell formation region 101. In this memory cell MC, a gate insulating film 2A is provided on the surface of a semiconductor substrate 1, and this gate insulating film 2A functions as a tunnel insulating film during data writing, that is, during charge injection into the charge storage layer 3A. The gate insulating film 2A is hereinafter called a tunnel insulating film 2A. In addition, this tunnel insulating film 2A functions as an electronic barrier to the charge in a charge storage layer 3A. The tunnel insulating film 2A is, for example, a silicon oxide film, and its thickness is about 3 nm to 5 nm to ensure the retention characteristics of the memory cell.

The charge storage layer 3A is provided on the tunnel insulating film 2A. The charge storage layer 3A retains a charge (electrons) and is thus responsible for data storage. The charge storage layer 3A is formed of an insulating film containing a large number of charge trapping levels, such as a silicon nitride film. The thickness of the charge storage layer (silicon nitride film) 3A is, for example, 3 nm to 10 nm.

A block insulating film 4A is provided on the charge storage layer 3A, and a gate electrode 10A is further provided on the block insulating film 4A. The block insulating film 4A prevents the charge trapped in the charge storage layer 3A from being released to the gate electrode 10A. A high-dielectric insulating film such as an alumina film (Al₂O₃), a hafnium oxide film (HfO₂), a tantalum oxide film (Ta₂O₃) or a lanthanum oxide film (La₂O₃) is used for the block insulating film 4A. When Al₂O₃ is used for the block insulating film 4A, its thickness is, for example, about 10 nm to 20 nm.

The gate electrode 10A has a stack structure composed of, for example, a conductive layer 6A on the block insulating film 4A, and a conductive layer 7A on the conductive layer 6A. The conductive layer 6A is, for example, a tantalum nitride film (TaN) 6A. The conductive layer 7A is, for example, a nickel silicide film (NiSi₂) 7A. The TaN film 6A functions to adjust the difference of work function between the block insulating film 4A and an electrode material with low resistivity (e.g., NiSi₂). In addition, instead of the TaN film 6A, a tantalum carbide film (TaC) or a polysilicon film, for example, may be used as the conductive layer 6A.

Furthermore, two diffusion layers 8A functioning as source/drain regions of the memory cell MC are provided in the semiconductor substrate 1.

As shown in FIG. 4, in the sectional structure of the memory cell MC in the channel width direction, the side surface of an isolation insulating film 9 is in contact with the side surface of the TaN film 6A, the side surface of the block insulating film 4A, the side surface of the charge storage layer 3A and the side surface of the gate insulating film 2A. Moreover, the NiSi₂ film 7A is in contact with the upper surface of the TaN film 6A and the upper surface of the isolation insulating film 9. In this case, the upper surface of the isolation insulating film 9 is in direct contact with the gate electrode 10A (NiSi₂ film 7A).

The select transistor STr is disposed in a select transistor formation region 102.

The select transistor STr has a gate insulating film 21 on the semiconductor substrate 1, and a gate electrode 10B on the gate insulating film 21. Further, two diffusion layers 8B functioning as source/drain regions of the select transistor STr are provided in the semiconductor substrate 1.

The gate electrode 10B is composed of a conductive layer 6B on the gate insulating film 21, and a conductive layer 7B. These layers 6B, 7B are equal in material and thickness to the TaN film 6A and the NiSi₂ film 7A constituting the gate electrode 10A of the memory cell MC, respectively. Hereinafter, the conductive layer 6B is called a TaN film 6B, and the conductive layer 7B is called a NiSi₂ film 7B.

Here, the gate insulating film 21 of the select transistor STr has a stack structure. Specifically, the gate insulating film 21 is composed of an insulating film 2B on the surface of the semiconductor substrate 1, and an insulating film 4B on the insulating film 2B. The insulating film 4B is configured with the same material and thickness as the block insulating film 4A of the memory cell MC. The insulating film 2B is, for example, a silicon oxide film, and its thickness is about 2 nm to 10 nm. The thickness of the gate insulating film 21 of the select transistor STr is preferably larger than the sum of the thickness of the tunnel oxide film 2A of the memory cell MC and the thickness of the block insulating film 4A.

In the sectional structure of the select transistor STr in the channel width direction, the side surface of the TaN film 6B and the side surface of the gate insulating film 21 are in contact with the side surface of the isolation insulating film 9, and the NiSi₂ film 7B is in contact with the upper surface of the TaN film 6B and the upper surface of the isolation insulating film 9.

As shown in FIGS. 3 and 4, the select transistor STr in the present embodiment includes no charge storage layer in the stack (hereinafter referred to as a gate stack) constituting its gate structure.

The low-breakdown-voltage MIS transistor LVTr is provided in the low-breakdown-voltage region 201. The low-breakdown-voltage MIS transistor LVTr has a gate insulating film 2C on the semiconductor substrate 1, the gate electrode 10C on the gate insulating film 2C. Further, two diffusion layers 8C functioning as source/drain regions are provided in the semiconductor substrate 1.

The gate insulating film 2C is, for example, a silicon oxide film, and its thickness is, for example, about 5 nm to 10 nm. The thickness of the gate insulating film 2C is smaller than the thickness of the gate insulating film 21 in the stack structure of the select transistor STr and larger than the thickness of the tunnel insulating film 2A. In addition, the thickness of the gate insulating film 2C may be the same as thickness of the gate insulating film 21 in the stack structure of the select transistor STr.

The gate electrode 10C is composed of a conductive layer 5C, a conductive layer 6C and a conductive layer 7C. The conductive layer 5C is, for example, a polysilicon film. The conductive layer 6C and the conductive layer 7C have the same configuration as the gate electrode 10A of the memory cell. That is, the conductive layer 6C is made of a TaN film, and the conductive layer 7C is made of a NiSi₂ film. Hereinafter, the conductive layer 5C is called a polysilicon film 5C, the conductive layer 6C is called a TaN film 6C, and the conductive layer 7C is called a NiSi₂ film 7C.

In the sectional structure of the low-breakdown-voltage MIS transistor LVTr in the channel width direction, the side surfaces of the TaN film 6C, the polysilicon film 5C and the gate insulating film 2C are in contact with the side surface of the isolation insulating film 9, and the NiSi₂ film 7C is in contact with the upper surface of the TaN film 6C and the upper surface of the isolation insulating film 9.

The high-breakdown-voltage MIS transistor HVTr is provided in the high-breakdown-voltage region 202.

The high-breakdown-voltage MIS transistor HVTr has a gate insulating film 2D on the semiconductor substrate 1, the gate electrode 10D on the gate insulating film 2D, and two diffusion layers 8D functioning as source/drain regions in the semiconductor substrate 1.

The gate insulating film 2D is, for example, a silicon oxide film, and its thickness is, for example, about 30 nm to 40 nm. The thickness of the gate insulating film 2D is larger than thickness of the gate insulating film 2C of the low-breakdown-voltage MIS transistor LVTr. The reason is that the high-breakdown-voltage MIS transistor HVTr is an element responsible for high-voltage transfer, so that its drive voltage is preferably higher than the drive voltage of the low-breakdown-voltage MIS transistor LVTr and ensures a sufficient gate breakdown voltage.

Furthermore, the gate electrode 10D has the same configuration as the gate electrode 10C of the low-breakdown-voltage MIS transistor LVTr, and is composed of three conductive layers. That is, the gate electrode 10D is composed of a polysilicon film 5D, a TaN film 6D of the same configuration as the gate electrode 10A of the memory cell, and a NiSi₂ film 7D.

Moreover, the structure in the channel width direction is similar to that of the low-breakdown-voltage MIS transistor. The side surfaces of the TaN film 6D, the polysilicon film 5D and the gate insulating film 2D are in contact with the side surface of the isolation insulating film 9, and the NiSi₂ film 7D is in contact with the upper surface of the TaN film 6D and the upper surface of the isolation insulating film 9.

As shown in FIGS. 3 and 4, the low-breakdown-voltage/high-breakdown-voltage MIS transistors LVTr, HVTr disposed in the peripheral circuit region are configured to include no charge storage layers in their gate stacks, similarly to the select transistor STr.

In the first embodiment of the present invention, the gate structure of the select transistor STr is configured to include no charge storage layer, similarly to the memory cell. No charge is therefore injected or accumulated in the gate stack even if a voltage is applied to the gate electrode 10B of the select transistor during writing/reading operation. Thus, there is no variation in the threshold voltage of the select transistor STr even if the writing/reading operation is repeatedly performed.

Furthermore, in the present embodiment, the gate insulating film 21 of the select transistor STr includes the insulating film 4B of the same configuration of as the block insulating film 4A of the memory cell MC. Also, the gate electrode 10B of the select transistor STr has the same configuration of as the gate electrode 10A of the memory cell MC.

If the gate structures of the memory cell MC and the select transistor STr are different from each other so that the select transistor STr includes no charge storage layer as heretofore, films to be formed on the gate insulating films have to be separately formed. In this case, different processes are required for the plurality of films constituting the gate stacks in the memory cell and the select transistor, resulting in an increased number of manufacturing steps.

Furthermore, when the gate insulating films and the gate electrodes are independently made in the memory cell MC and the select transistor STr, a plurality of lithography processes are required for the respective elements in the manufacturing process of the memory cell and the manufacturing process of the select transistor, resulting in a further increased manufacturing steps. Moreover, when the lithography processes are carried out for the respective elements, the distance between the memory cell formation region 101 and the select transistor formation region 102 needs to be increased to ensure a process margin. This leads to the problem of an increased chip area and an increased manufacturing cost.

In contrast, in the first embodiment of the present invention, the gate insulating film 21 and the gate electrode 10B of the select transistor STr are formed of about the same films as the film constituting the memory cell MC. Thus, the films constituting the select transistor STr and the memory cell MC can be formed substantially at the same time.

Furthermore, the select transistor STr merely includes no thin charge storage layer, and the select transistor STr and the memory cell MC have about the same gate structure, and moreover, the gate electrodes and the gate insulating films of the memory cell MC and the select transistor can be fabricated at the same time. This allows the reduction of the manufacturing cost.

Moreover, in this structure, one lithography process has only to be performed for the memory cell and the select transistor, and it is therefore not necessary to increase the distance between the memory cell and the select transistor. This allows the reduction of the chip area and thus the reduction of the manufacturing cost.

Likewise, the low-breakdown-voltage/high-breakdown-voltage MIS transistors LVTr, HVTr include no charge storage layers, and the variations of the threshold voltages of the MIS transistors can thus be prevented. Moreover, since the configurations of the gate electrodes 10C, 10D are partly the same as the configuration of the gate electrode 10A, gate fabrication can be performed simultaneously with the memory cell. This holds down the manufacturing cost of the flash memory.

As described above, according to the first embodiment of the present invention, the variations of the threshold voltages of the select transistor and the peripheral transistor included in the nonvolatile semiconductor memory can be prevented, and the operation of the flash memory can be stable. Moreover, according to the first embodiment of the present invention, it is possible to hold down an increase in the number of manufacturing steps and an increase in the chip area, and the manufacturing cost of the nonvolatile semiconductor memory can therefore be reduced.

(c) Manufacturing Method

One example of a method of manufacturing the nonvolatile semiconductor memory according to the present embodiment will be described below with reference to FIGS. 3 to 11.

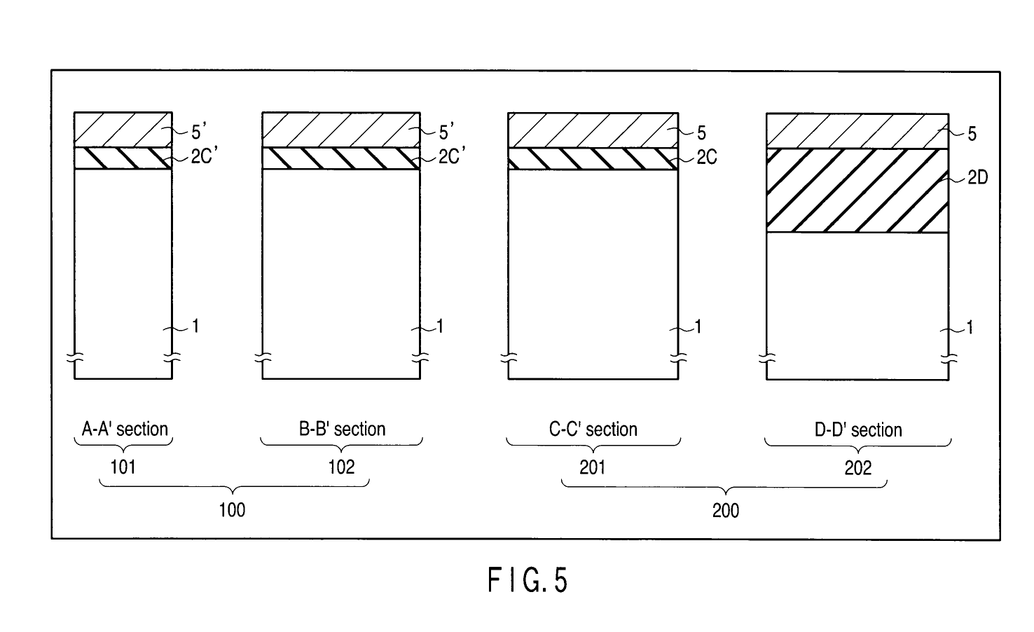

Initially, as shown in FIG. 5, well regions (not shown) with predetermined impurity concentration are formed in a semiconductor substrate 1 (e.g., a silicon substrate) by, for example, an ion implantation method in a memory cell formation region 101, a select transistor formation region 102, a low-breakdown-voltage region 201 and a high-breakdown-voltage region 202.

Then, for example, a silicon oxide film 2D serving as part of a gate insulating film of a high-breakdown-voltage MIS transistor is formed with a thickness of about 30 nm to 40 nm on the surface of the semiconductor substrate 1 in the high-breakdown-voltage region 202 by a thermal oxidation method. At this point, silicon oxide films formed in the other element formation regions 101, 102, 202 are removed using a photolithographic technique and a reactive ion etching (RIE) method. As a result, the surface of the semiconductor substrate 1 in the memory cell formation region 101, the select transistor formation region 102 and the low-breakdown-voltage region 201 is exposed.

Then, new silicon oxide films 2C, 2C′ are formed with a thickness of about 5 nm to 10 nm on the exposed surface of the semiconductor substrate 1 by, for example, the thermal oxidation method. The silicon oxide film 2C formed in the low-breakdown-voltage region 201 serves as a gate insulating film of a low-breakdown-voltage MIS transistor. Further, polysilicon films 5, 5′ serving as parts of gate electrodes of the low-breakdown-voltage/high-breakdown-voltage MIS transistors are deposited on the silicon oxide films 2C, 2C′, 2D by, for example, a CVD method.

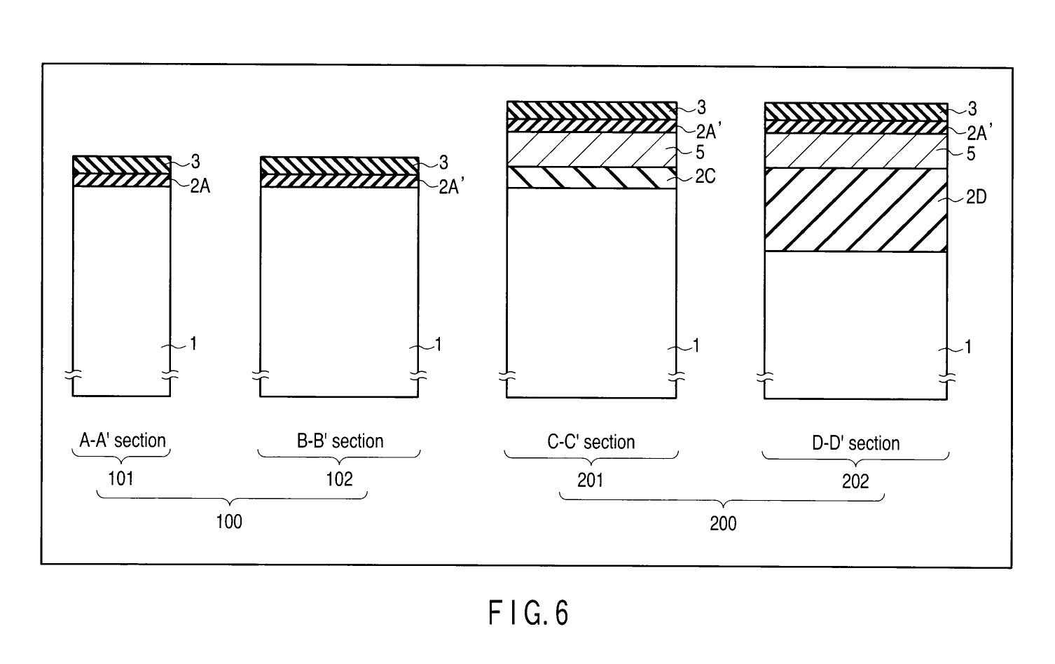

As shown in FIG. 6, the silicon oxide films and the polysilicon films in the memory cell and select transistor formation regions 101, 102 are removed by the lithographic technique and the RIE method. Subsequently, silicon oxide films 2A, 2A′ are formed with a thickness of about 3 nm to 5 nm on the surface of the semiconductor substrate 1 in the memory cell formation region 101 and the select transistor formation region 102 by, for example, the thermal oxidation method. The silicon oxide film 2A serves as a gate insulating film (tunnel insulating film) of a memory cell. Then, for example, a silicon nitride film 3 serving as a charge storage layer of the memory cell is formed with a thickness of about 3 nm to 10 nm on the silicon oxide films 2A, 2A′ by, for example, the CVD method.

In addition, in this step, the silicon oxide film 2A′ is formed on the polysilicon film 5 in the low-breakdown-voltage/high-breakdown-voltage region 201, 202 simultaneously with the formation of the silicon oxide film 2A. The silicon nitride film 3 is formed on the silicon oxide film 2A′.

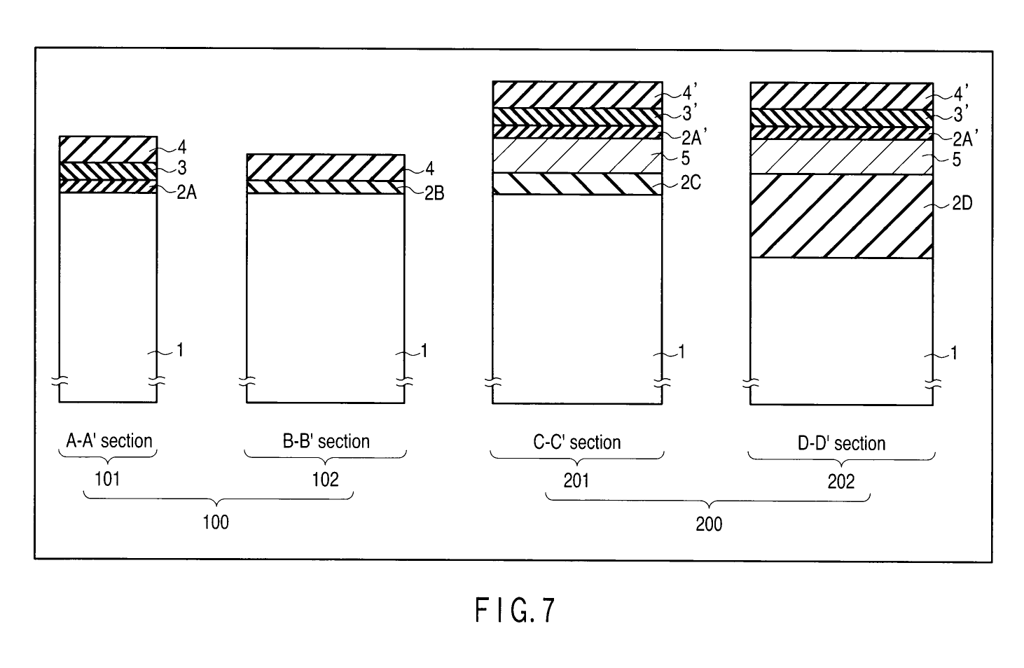

Then, as shown in FIG. 7, the silicon nitride film and the silicon oxide film in the select transistor formation region 102 are removed by the lithographic technique and the RIE method. On the surface of the semiconductor substrate 1 exposed by the removal of these films, a silicon oxide film 2B serving as part of a gate insulating film of a select transistor is formed by, for example, the thermal oxidation method.

Then, an Al₂O₃ film 4 is formed with a thickness of about 10 nm to 20 nm on the silicon nitride film 3 in the memory cell formation region 101 by, for example, an atomic layer deposition (ALD) method. At the same time, the Al₂O₃ film 4 is formed on the silicon oxide film 2B in the select transistor formation region 102 and on silicon nitride films 3′ in the low-breakdown-voltage/high-breakdown-voltage regions 201, 202.

The Al₂O₃ film 4 serves as a block insulating film of the memory cell and also serves as part of a gate insulating film of the select transistor.

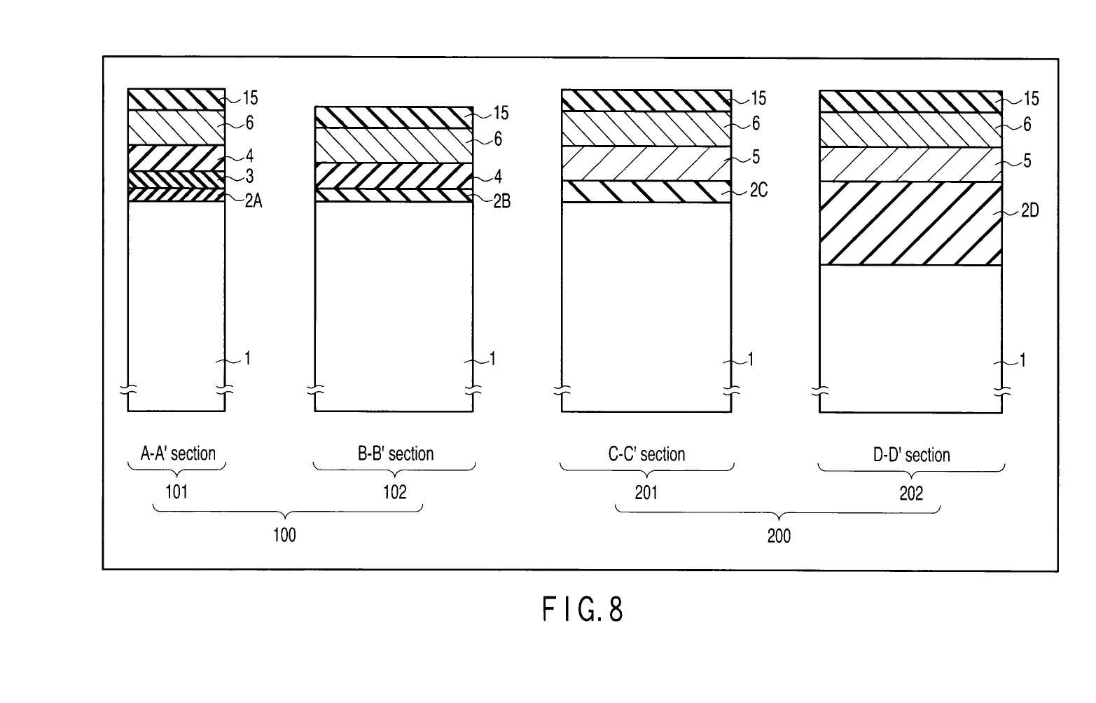

As shown in FIG. 8, the Al₂O₃ film, the silicon nitride film, and the silicon oxide film on the polysilicon film 5 in the low-breakdown-voltage/high-breakdown-voltage regions 201, 202 are removed by, for example, the photolithographic technique and the RIE method. Then, a TaN film 6 is formed on the Al₂O₃ film 4 in the memory cell formation region 101 and the select transistor formation region 102. At the same time, the TaN film 6 is deposited on the polysilicon film 5 in the low-breakdown-voltage/high-breakdown-voltage regions 201, 202. The TaN film 6 is a conductive material serving as parts of the gate electrodes of the respective elements. However, the material is not limited to the TaN film 6, and any other material may be used as long as such a material can adjust the difference of work function between the Al₂O₃ film (high-dielectric film) and the gate electrode material with low resistivity.

Then, a silicon nitride film 15 serving as a mask material is deposited on the TaN film 6.

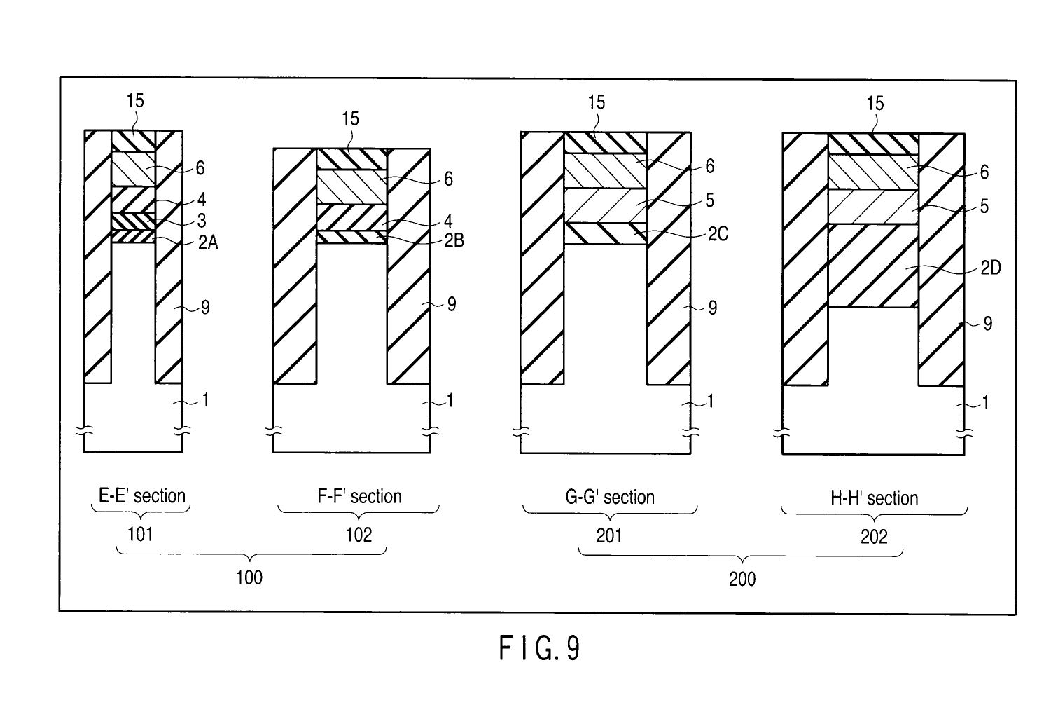

As shown in FIG. 9 which is a sectional view in the channel width direction, a mask pattern for fabrication in the channel width direction is formed in the silicon nitride film 15 in the element regions 101, 102, 201, 202 by, for example, the photolithographic technique. In accordance with the formed mask pattern, the silicon nitride film (mask material) 15, the TaN film, the Al₂O₃ film, the silicon nitride film (charge storage layer) 3, the silicon oxide films 2A, 2B, 2C, 2D and the semiconductor substrate 1 are sequentially etched by, for example, the RIE method in the regions 101, 102, 201, 202 in the simultaneous steps. As a result, trenches of, for example, as STI structure serving as isolation regions are formed in the semiconductor substrate 1. Further, a silicon oxide film 9 is embedded in the trenches by the CVD method and a chemical mechanical polishing (CMP) method using the mask material 15 as a stopper.

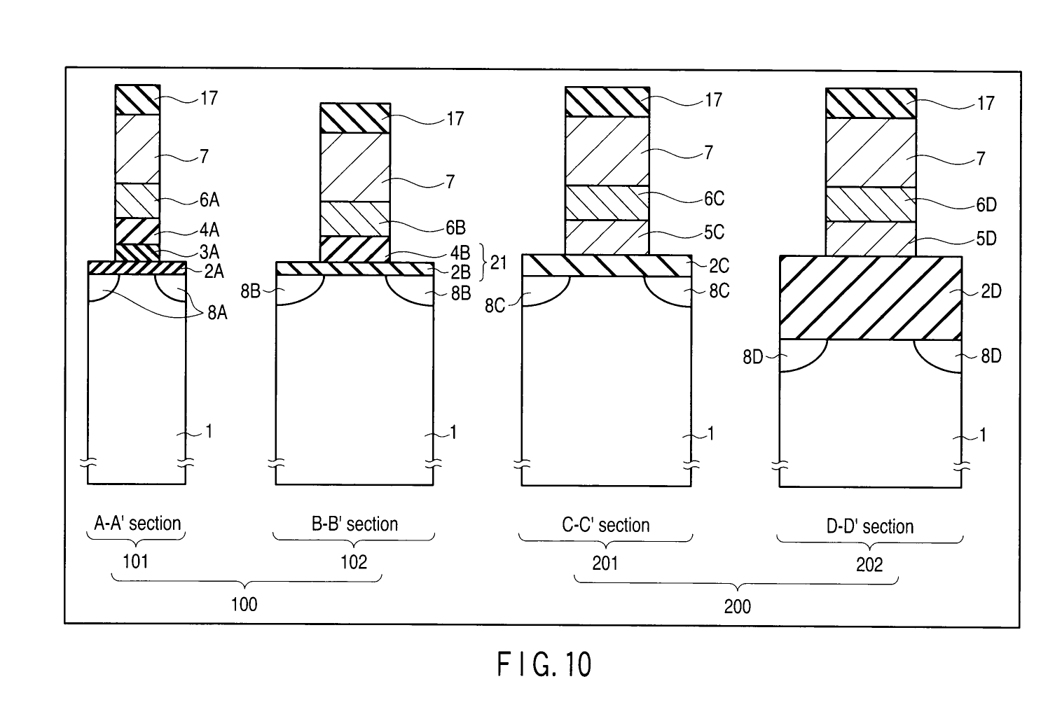

The subsequent steps are described using sectional views of the elements along the channel length direction for brevity. As shown in FIG. 10, after the silicon nitride film (mask material) on the TaN film 6 has been removed, a polysilicon film 7 is formed on the TaN film 6, and a silicon nitride film 17 serving as a mask material during the gate fabrication is deposited on the polysilicon film 7.

Then, a mask pattern for fabrication in the channel length direction is formed in the silicon nitride film 17 in the element regions 101, 102, 201, 202 by, for example, the photolithographic technique. In accordance with the formed mask pattern, the polysilicon film, the TaN film, the Al₂O₃ film and the silicon nitride film (charge storage layer) are sequentially etched in the regions 101, 102, 201, 202 in the simultaneous steps.

As a result, stacks (gate stacks) constituting the gate electrodes of the memory cell MC, the select transistor STr, the low-breakdown-voltage MIS transistor LVTr and the high-breakdown-voltage MIS transistor HVTr are formed. In addition, the silicon oxide film on the surface of the semiconductor substrate 1 may be etched at this point.

Then, diffusion layers 8A, 8B, 8C, 8D serving as source/drain regions are formed in a self-aligning manner in the formed gate stacks in the semiconductor substrate 1 in the regions 101, 102, 201, 202 by, for example, the ion implantation method.

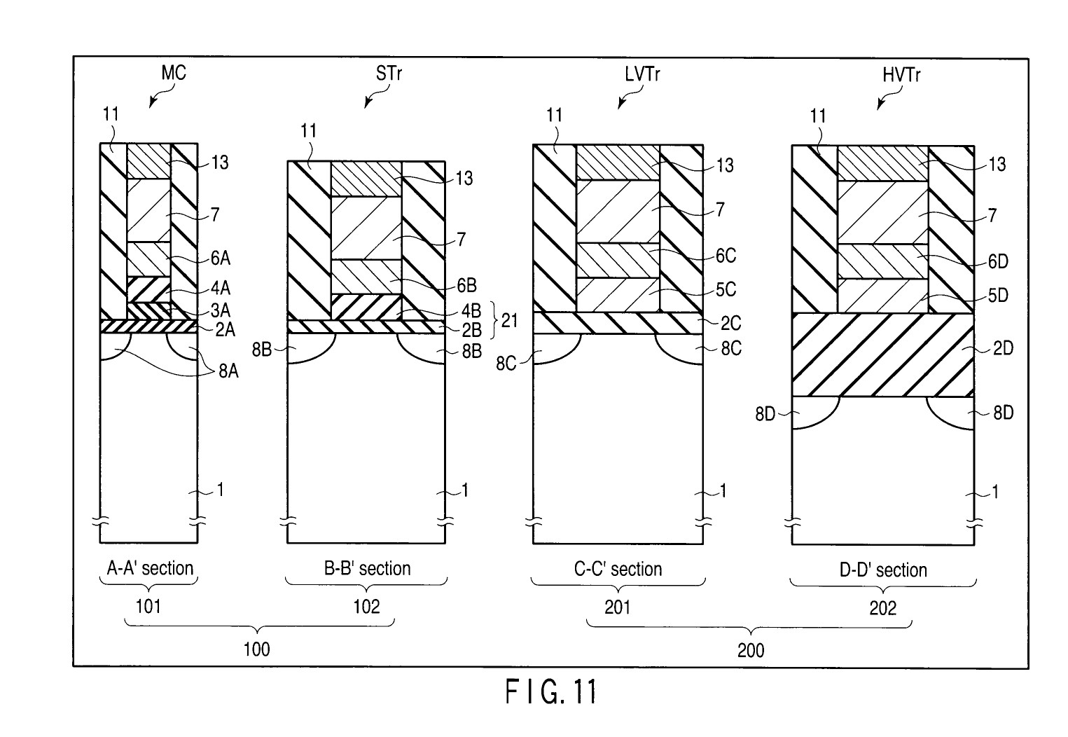

After the gate fabrication, an interlayer insulating film 11 is formed, and the silicon nitride film as the mask material is removed, as shown in FIG. 11. Then, for example, a nickel (Ni) film is deposited on the exposed surface of the polysilicon film 7 by a sputtering method. Subsequently, a heating treatment is provided for the silicidation of the polysilicon film 7.

The conditions of this heating treatment preferably enable the following structure to be obtained. In the gate stacks of the memory cell MC and the select transistor STr, the polysilicon film 7 is completely silicided, and a two-layer structure of the NiSi₂ film and the TaN film 6A, 6B is formed. At the same time, in the stacks forming the gates of the low-breakdown-voltage/high-breakdown-voltage MIS transistors, a three-layer structure is formed in which the NiSi₂ film, the TaN film 6C, 6D and the polysilicon film 5C, 5D are stacked. The reason is that a low resistance value is preferable in the memory cell MC and the select transistor STr because the gate electrode functions as a word line and a select gate line and that the gate electrode of a polycide structure is preferable in the peripheral transistor in order to inhibit the variation of the threshold voltage.

As a result of the silicide processing under such conditions, the gate electrode 10A of the memory cell MC, the gate electrode 10B of the select transistor STr, part of the gate electrode 10C of the low-breakdown-voltage MIS transistor LVTr and part of the gate electrode 10D of the high-breakdown-voltage MIS transistor HVTr serve as the NiSi₂ films, as shown in FIG. 3. Further, part of the gate electrode 10C of the low-breakdown-voltage MIS transistor LVTr and part of the gate electrode 10D of the high-breakdown-voltage MIS transistor HVTr serve as the polysilicon films 5C, 5D. Moreover, in the gate electrodes 10C, 10D of the low-breakdown-voltage/high-breakdown-voltage MIS transistors LVTr, HVTr, the TaN films 6C, 6D are interposed between the NiSi₂ films 7C, 7D and the polysilicon films 5C.

Then, contacts and an upper interconnect layer are formed by use of generally known techniques, such that a flash memory is completed.

As a result of the process described above, the select transistor STr and the low-breakdown-voltage/high-breakdown-voltage MIS transistors LVTr, HVTr can be configured to include no charge storage layers 3A in their gate stacks.

It is thus possible to provide a flash memory in which the threshold voltages of the select transistor STr and the low-breakdown-voltage/high-breakdown-voltage MIS transistors do not vary during the operation of the flash memory.

Furthermore, in the memory cell, the select transistor STr and the low-breakdown-voltage/high-breakdown-voltage MIS transistors manufactured by the manufacturing process described above, the insulating films and the conductive layers included in their gate stacks are stacked with about the same configuration.

Thus, etching steps for the gate fabrication in the respective elements can be performed at the same time in the manufacturing process of the flash memory.

Consequently, according to the first embodiment of the present invention, it is possible to provide a flash memory (nonvolatile semiconductor memory) which is capable of stable operation and which can reduce the manufacturing cost.

In addition, in the configurations of the gate electrodes 10A, 10B, 10C, 10D of the elements MC, STr, LVTr, HVTr, polysilicon films may be formed instead of the TaN films 6A, 6B, 6C, 6D. In this case, the gate electrodes 10A, 10B of the memory cell MC and the select transistor STr have a single-layer structure of the NiSi₂ film, while the gate electrodes of the MIS transistors LVTr, HVTr have a two-layer structure of the polysilicon film and the NiSi₂ film.

Furthermore, in part of the gate electrode 10A of the memory cell MC, part of the gate electrode 10B of the select transistor STr, part of the gate electrode 10C of the low-breakdown-voltage MIS transistor LVTr and part of the gate electrode 10D of the high-breakdown-voltage MIS transistor HVTr, a stack film made up of tungsten nitride (WN) and tungsten (W) may be used instead of the NiSi₂ film. Moreover, low-resistance metal materials such as aluminum (Al) and copper (Cu) may be used to form the gate electrodes 10A, 10B, 10C, 10D.

(d) Modification

(d-1) First Modification

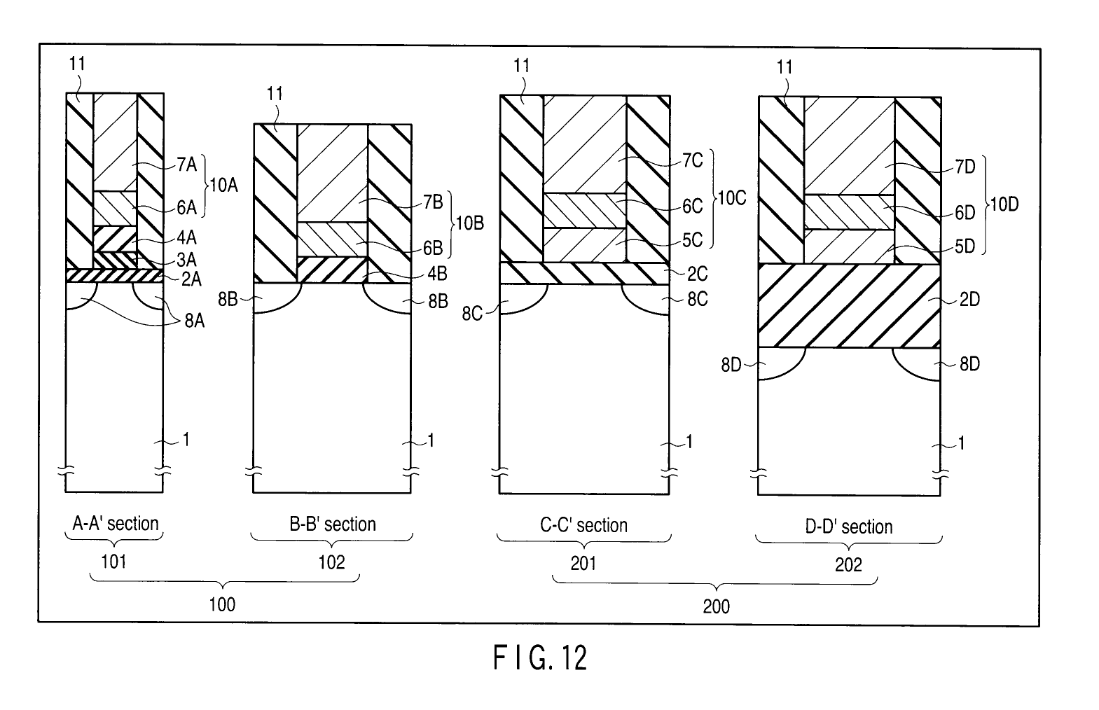

A first modification of the flash memory according to the first embodiment of the present invention will be described with FIG. 12. It is to be noted that the same signs are assigned to the same parts as described above and detailed explanations are omitted.

As shown in FIG. 12, the gate insulating film of the select transistor STr may be formed solely by the insulating film 4B of the same configuration as the block insulating film of the memory cell in the first embodiment. That is, in the structure shown in FIG. 12, an insulating film 4B of the same configuration as a block insulating film 4A is in direct contact with the surface of a semiconductor substrate 1 in a select transistor formation region 102.

In the case of the formation of the structure shown in FIG. 12, the step (step corresponding to FIG. 7) of forming the gate insulating film 2B of the select transistor can be eliminated in the structure shown in FIG. 3, and the manufacturing cost of the flash memory can be further reduced.

The structure shown in FIG. 12 can provide the same effects as in the flash memory according to the first embodiment of the present invention.

That is, the operation of the flash memory can be stable, and the manufacturing cost of the flash memory can be reduced.

(d-2) Second Modification

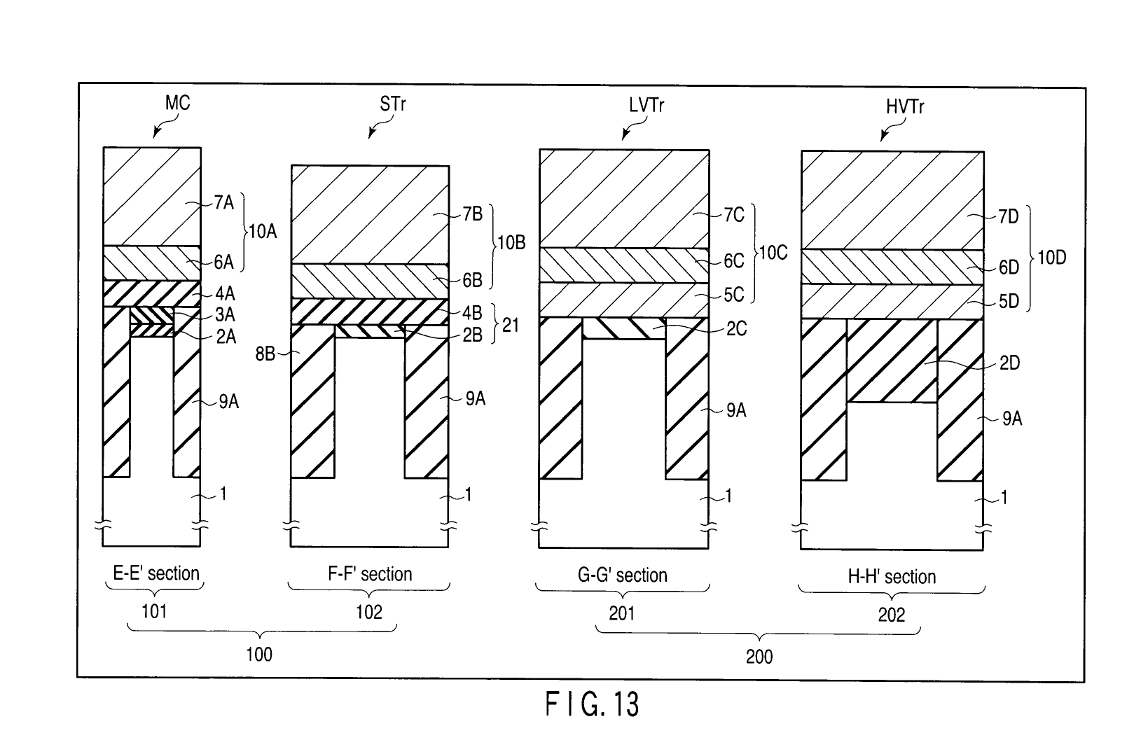

A second modification of the flash memory according to the first embodiment will be described with FIG. 13. It is to be noted that the same signs are assigned to the same parts as described above and detailed explanations are omitted.

In the example shown in FIG. 4, the side surfaces of the part (TaN film) 6A of the gate electrode 10A, the block insulating film 4A, the charge storage layer 3A and the gate insulating film 2A are in contact with the side surface of the isolation insulating film 9 in the structure of the memory cell MC in the channel width direction.

The reason is that the element region forming steps are performed after the formation of the TaN film 6 (see FIG. 9) and that the element regions are formed in a self-aligning manner in part of the gate electrode 10A and the lower films.

In the other elements STr, LVTr, HVTr in which the element region forming steps are performed simultaneously with the memory cell MC, the side surfaces of the TaN films 6B, 6C, 6D and the lower films are in contact with the isolation insulating film 9.

However, the first embodiment of the present invention is not limited to the structure in the channel width direction shown in FIG. 4. For example, the structure shown in FIG. 13 is also acceptable.

As shown in FIG. 13, in a memory cell MC, a block insulating film 4A is in contact with the upper surface of a charge storage layer 3A and the upper surface of an isolation insulating film 9A. Further, part (TaN film) 6A of a gate electrode 10A provided on the block insulating film 4A extends in the channel width direction above the isolation insulating film 9A. That is, in the example shown in FIG. 13, the upper surface of the isolation insulating film 9A is in direct contact with the block insulating film 4A and is not in contact with the gate electrode 10A.

In the structure shown in FIG. 13, element region forming steps are performed before the formation of the block insulating film 4A. More specifically, in the step shown in FIG. 6, the silicon nitride film 3 and the lower films are sequentially etched using the photolithographic technique and the RIE method, and trenches serving as isolation regions are formed in a semiconductor substrate 1. Then, the isolation insulating film 9A is embedded in the formed trenches, such that element regions are formed. Further, a silicon oxide film 2A′ and the silicon nitride film 3 are removed in a select transistor formation region 102, and a silicon oxide film 2B is formed on the surface of a semiconductor substrate 1. Then, as in the step shown in FIG. 7, after an Al₂O₃ film 4 has been formed on a charge storage layer 3A, silicon oxide films 2B, 2C, 2D and the isolation insulating film 9A, gate electrodes 10A, 10B, 10C, 10D in the respective elements are formed in about the same steps as in FIGS. 8 to 11.

As a result of the process described above, the structure shown in FIG. 13 is formed.

In addition, as in the first modification, the Al₂O₃ film 4 may be formed on the surface of the semiconductor substrate 1 without forming the silicon oxide film 2B in the select transistor formation region 102.

The structure shown in FIG. 13 enables the stable operation of the flash memory and the reduced manufacturing cost of the flash memory, as in the flash memory shown in FIGS. 3 and 4. Moreover, a voltage applied to the gate electrode 10A more easily propagates to the charge storage layer 3A. As a result, the writing voltage and erasing voltage of the memory cell MC can be decreased.

### (2) Second Embodiment

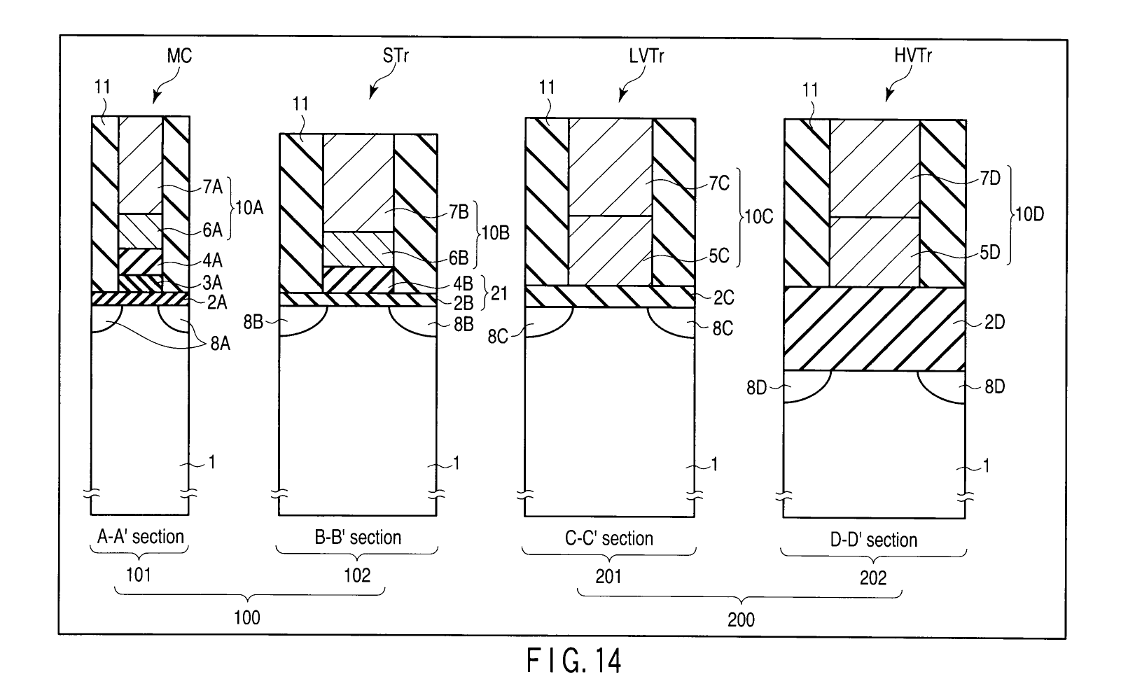

A flash memory according to a second embodiment of the present invention will be described with FIG. 14. It is to be noted that the same signs are assigned to parts having about the same functions as in the first embodiment and detailed explanations are omitted.

In the first embodiment, part of the configuration of the gate electrodes 10C, 10D of the low-breakdown-voltage/high-breakdown-voltage MIS transistors LVTr, HVTr is the same as the overall configuration of the conductive layers included in the gate electrode 10A of the memory cell MC. In contrast, the second embodiment of the present invention is different in that part of gate electrodes 10C, 10D of low-breakdown-voltage/high-breakdown-voltage MIS transistors LVTr, HVTr is the same as part of a gate electrode 10A of a memory cell MC.

The structures of the elements MC, STr, LVTr, HVTr are more specifically described below.

FIG. 14 shows the sectional structures of the memory cell MC, the select transistor STr and the low-breakdown-voltage/high-breakdown-voltage MIS transistors LVTr, HVTr along the channel length direction in the flash memory according to the second embodiment of the present invention. It is to be noted that the structure of each element in the channel width direction has only to be the same as one of the structures shown in, for example, FIGS. 4 and 13, and is not specifically described.

As shown in FIG. 14, the gate structure (gate stack) of the memory cell MC has a configuration in which a tunnel insulating film 2A on a semiconductor substrate 1, a charge storage layer 3A, a block insulating film 4A and a gate electrode 10A are stacked. Further, the memory cell MC has diffusion layers 8A serving as source/drain regions in the semiconductor substrate 1.

The gate electrode 10A of the memory cell MC has a configuration in which a TaN film 6A and a NiSi₂ film 7A are stacked.

The gate structure of the select transistor STr is composed of a gate insulating film 21 on the surface of the semiconductor substrate 1, and a gate electrode 10B.

The gate insulating film 21 has a stack structure in which an insulating film 4B is provided on an insulating film 2B. The insulating film 2B is, for example, a silicon oxide film, and the insulating film 4B has the same configuration as the block insulating film (e.g., Al₂O₃ film) 4A. However, the gate insulating film 21 may have a single-layer structure of the insulating film 4B similar to the structure shown in FIG. 12.

The gate electrode 10B has the same configuration as the gate electrode 10A of the memory cell MC. That is, the gate electrode 10B is composed of the TaN film 6A and the NiSi₂ film 7A.

The gate structure of the low-breakdown-voltage MIS transistor LVTr is composed of a gate insulating film 2C provided on the surface of the semiconductor substrate 1, and a gate electrode 10C. Further, the low-breakdown-voltage MIS transistor LVTr has diffusion layers 8C as source/drain regions in the semiconductor substrate 1.

The gate electrode 10C has a stack structure composed of a polysilicon film 5C and a NiSi₂ film 7C. That is, in the gate electrode 10C, the NiSi₂ film 7C alone has the same configuration as the gate electrode 10A of the memory cell MC.

The gate structure of the high-breakdown-voltage MIS transistor HVTr is composed of a gate insulating film 2D provided on the surface of the semiconductor substrate 1, and a gate electrode 10D on the gate insulating film 2D. Further, diffusion layers 8D as source/drain regions are provided in the semiconductor substrate 1.

The gate electrode 10D of the high-breakdown-voltage MIS transistor HVTr has a stack structure composed of a polysilicon film 5D and a NiSi₂ film 7D. As in the low-breakdown-voltage MIS transistor LVTr, the NiSi₂ film 7D alone has the same configuration as the gate electrode 10A of the memory cell MC.

In addition, the relation of the thickness of the gate insulating films of the respective elements in the present embodiment is as follows: The thickness of the gate insulating film 21 of the select transistor STr is preferably larger than the sum of the thickness of the tunnel oxide film 2A of the memory cell MC and the thickness of the block insulating film 4A. Further, the thickness of the gate insulating film 2C of the low-breakdown-voltage MIS transistor LVTr is smaller than the thickness of the gate insulating film 2B in the stack structure of the select transistor STr and larger than the thickness of the tunnel insulating film 2A. The thickness of the gate insulating film 2D of the high-breakdown-voltage MIS transistor HVTr is larger than the thickness of the gate insulating film 2C of the low-breakdown-voltage MIS transistor LVTr.

The structure shown in FIG. 14 is formed in the following manufacturing process.

In the steps shown in FIGS. 7 and 8 in the first embodiment, the Al₂O₃ film 4′, the silicon nitride film 3′ and the silicon oxide film 2A′ in the low-breakdown-voltage/high-breakdown-voltage regions 201, 202 are removed immediately after the Al₂O₃ film 4, 4′ have been formed. In the present embodiment, the step of removing the films 4′, 3′, 2A′ is performed after the TaN film 6 has been formed, and not only the films 4′, 3′, 2A′ but also the TaN film 6 is removed in the low-breakdown-voltage/high-breakdown-voltage regions 201, 202. Subsequently, a polysilicon film 7 is deposited as in the step shown in FIG. 10, resulting in a structure in which the polysilicon film 7 is stacked on the polysilicon film 5. Then, the polysilicon film 7 alone is silicided by silicidation under predetermined conditions, such that the structures of the elements MC, STr, LVTr, HVTr shown in FIG. 14 are formed.

In the flash memory according to the second embodiment of the present invention as well, the gate structures of the select transistor STr and the low-breakdown-voltage/high-breakdown-voltage MIS transistors LVTr, HVTr include no charge storage layers, but partly include the same configuration as the gate structure of the memory cell MC. Thus, as in the effects described in the first embodiment, the variation of the threshold voltage can be prevented, and gate fabrication can be performed simultaneously.

The following effects can be further obtained in the second embodiment of the present invention. No TaN films are provided in the gate electrodes 10C, 10D of the low-breakdown-voltage/high-breakdown-voltage MIS transistors LVTr, HVTr, thus providing the gate electrodes different in configuration from the gate electrodes of the memory cell MC and the select transistor STr. As a result, optimum materials can be selected for the low-breakdown-voltage/high-breakdown-voltage MIS transistors LVTr, HVTr, the memory cell MC and the select transistor STr, so that the characteristics of the elements can be improved. As one example of the characteristic improvements, a silicide film or metal film can be used for the gate electrodes 10A, 10B of the memory cell MC and the select transistor STr in order to reduce resistance, and the polycide structure can be used for the gate electrodes 10C, 10D of the low-breakdown-voltage/high-breakdown-voltage MIS transistors LVTr, HVTr in order to inhibit the variation of the threshold voltage.

Moreover, as photolithography and etching steps are not performed directly to the block insulating film 4A, the block insulating film 4A is not damaged by the photolithography and etching steps. This prevents the deterioration of the block insulating film 4A and the characteristic deterioration of the memory cell MC.

As described above, according to the second embodiment of the present invention, the operation of the flash memory can be stable, and the manufacturing cost of the flash memory can be reduced. Moreover, the characteristic deterioration of the flash memory can be inhibited.

### (3) Third Embodiment

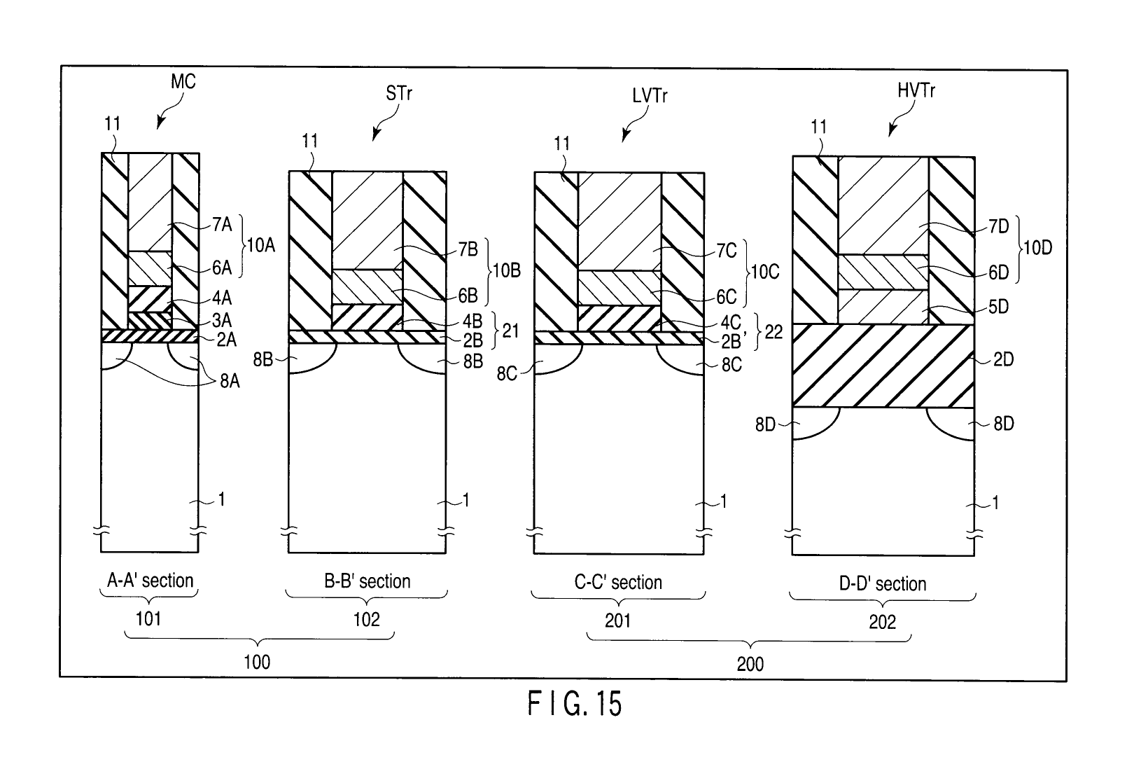

A flash memory according to a third embodiment of the present invention will be described with FIGS. 15 to 17. It is to be noted that the same signs are assigned to parts having about the same functions as in the first and second embodiments and detailed explanations are omitted.

The third embodiment is characterized in that a low-breakdown-voltage MIS transistor LVTr has the same structure as a select transistor STr. A more concrete explanation is given below with FIG. 15.

FIG. 15 shows the sectional structures of a memory cell MC, the select transistor STr and the low-breakdown-voltage/high-breakdown-voltage MIS transistors LVTr, HVTr along the channel length direction in the flash memory according to the third embodiment of the present invention. It is to be noted that the structure of each element in the channel width direction has only to be the same as one of the structures shown in, for example, FIGS. 4 and 13, and is not specifically described here.

As shown in FIG. 15, the gate structure (gate stack) of the memory cell MC has a structure in which a tunnel insulating film 2A on a semiconductor substrate 1, a charge storage layer 3A, a block insulating film 4A and a gate electrode 10A are stacked as in the first embodiment. Further, the memory cell MC has diffusion layers 8A serving as source/drain regions in the semiconductor substrate 1.

The gate electrode 10A has a stack structure composed of a TaN film 6A and a NiSi₂ film 7A.

The select transistor STr also has a structure similar to that in the first embodiment. This gate structure has a gate insulating film 21 on the surface of the semiconductor substrate 1, and a gate electrode 10B.

The gate insulating film 21 has a structure in which an insulating film 2B (e.g., a silicon oxide film) and an insulating film 4B (e.g., Al₂O₃ film) of the same configuration as the block insulating film are stacked. However, the gate insulating film 21 may have a single-layer structure of the insulating film 4B similar to the structure shown in FIG. 12. Similarly to the gate electrode 10A of the memory cell MC, the gate electrode 10B is composed of a TaN film 6B and a NiSi₂ film 7B.

Furthermore, the gate structure of the high-breakdown-voltage MIS transistor HVTr is composed of a gate insulating film 2D on the semiconductor substrate 1, and a gate electrode 10D on the gate insulating film 2D. The gate electrode 10D has a structure in which a polysilicon film 5D, a TaN film 6D and a NiSi₂ film 7D are stacked. Here, the gate electrode 10D of the high-breakdown-voltage MIS transistor HVTr partly includes films of the same configuration as the gate electrode 10A of the memory cell MC, that is, the TaN film 6D and the NiSi₂ film 7D.

Moreover, as shown in FIG. 15, the gate structure of the low-breakdown-voltage MIS transistor LVTr is composed of a gate insulating film 22 on the surface of the semiconductor substrate 1, a gate electrode 10C on the gate insulating film 22, and diffusion layers 8C serving as source/drain regions.

The gate insulating film 22 has a stack structure composed of an insulating film 2B′ of the same configuration as the insulating film 2B constituting the gate insulating film 21 of the select transistor STr, and an insulating film 4C of the same configuration as the block insulating film 4A. The gate electrode 10C is composed of a TaN film 6C and a NiSi₂ film 7C.

That is, the low-breakdown-voltage MIS transistor LVTr has about the same structure as the select transistor STr.

Thus, the low-breakdown-voltage MIS transistor LVTr and the select transistor STr have the same structure, such that their formation processes can be simplified. In particular, the gate insulating films 21, 22 can be formed at the same time, and the manufacturing cost can be reduced accordingly.

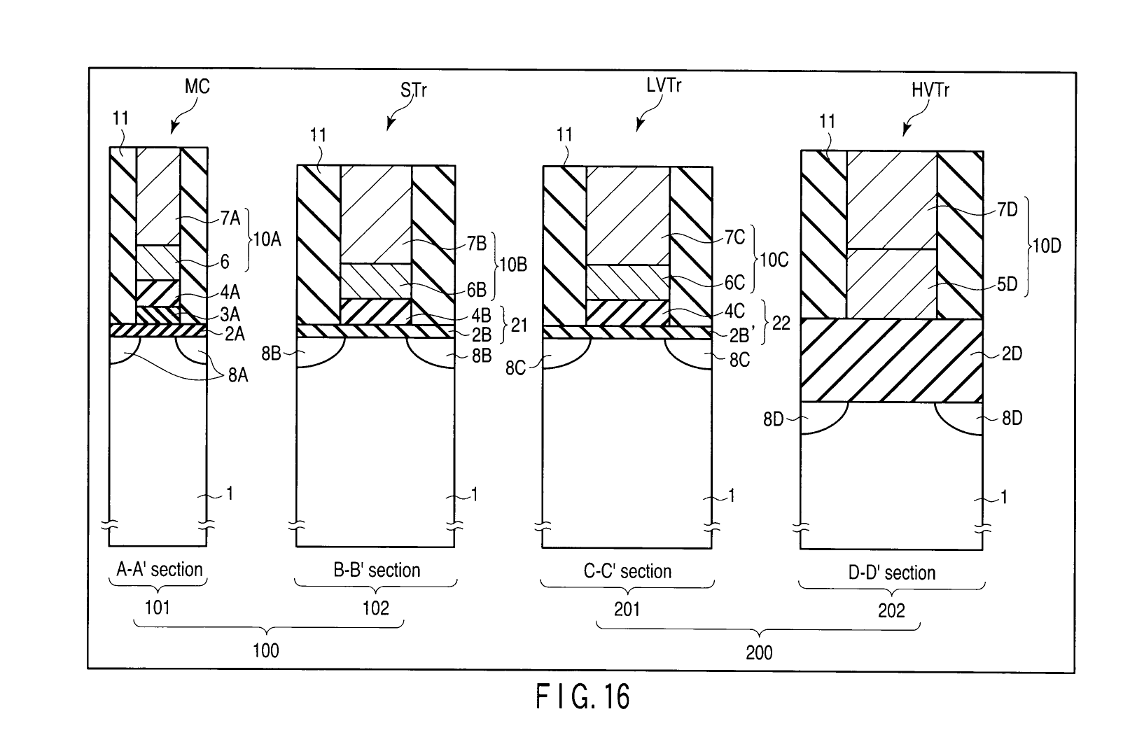

In addition, it is only necessary that the low-breakdown-voltage MIS transistor LVTr and the select transistor STr have the same structure. As shown in FIG. 16, the gate electrode 10D of the high-breakdown-voltage MIS transistor HVTr may have a two-layer structure of the polysilicon film 5D and the NiSi₂ film 7D.

Moreover, it is only necessary that the select transistor STr and the low-breakdown-voltage MIS transistor LVTr have the same configuration. The gate insulating film 21, 22 may be a single-layer film of the insulating film 4B, 4C of the same configuration as the block insulating film 4A.

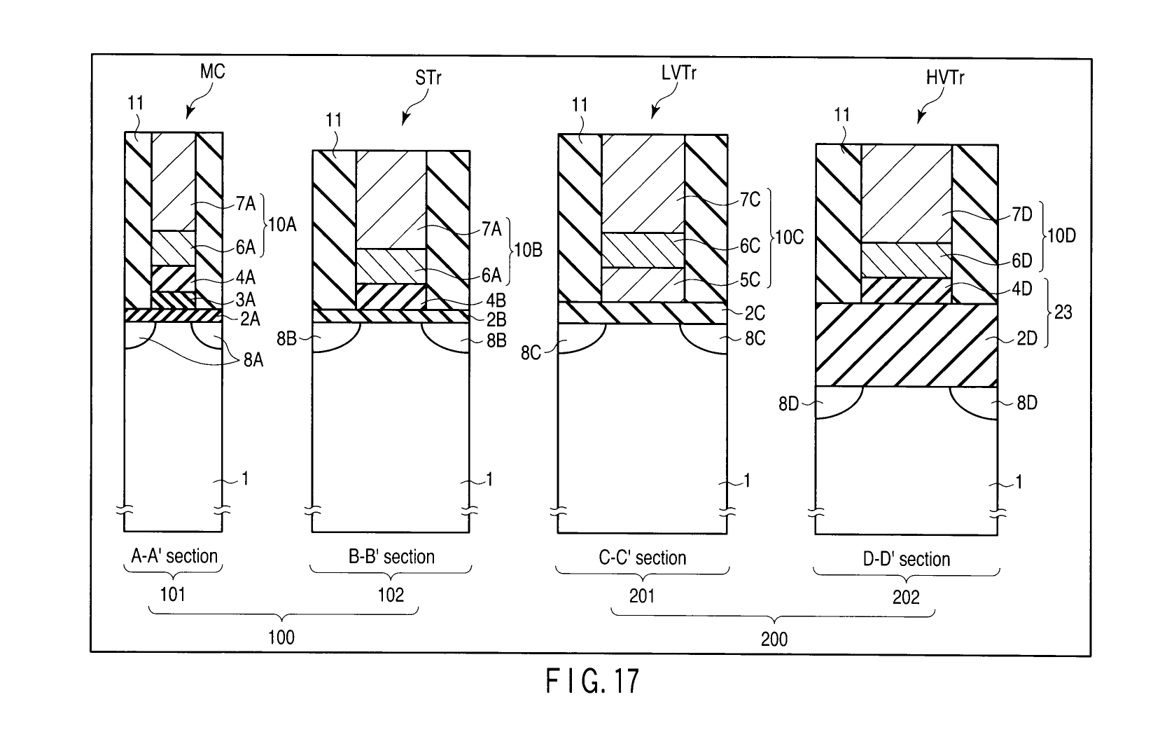

Furthermore, as shown in FIG. 17, instead of the low-breakdown-voltage MIS transistor LVTr, the high-breakdown-voltage MIS transistor HVTr may have about the same configuration as the select transistor STr. That is, a gate insulating film 23 of the high-breakdown-voltage MIS transistor HVTr may have a stack structure of an insulating film 2D and an insulating film 4D of the same configuration as the block insulating film 4A. The gate electrode 10D may be composed of the TaN film 6D and the NiSi₂ film 7D, similarly to the gate electrode 10A of the memory cell.

In addition, in the present embodiment, the relation of the thickness of the gate insulating films of the respective elements shown in FIGS. 15 to 17 is as follows: The thickness of the gate insulating film 21 of the select transistor STr is preferably larger than the sum of the thickness of the tunnel oxide film 2A of the memory cell MC and the thickness of the block insulating film 4A.

Furthermore, when the select transistor STr and the low-breakdown-voltage MIS transistor LVTr have about the same structure (FIGS. 15 and 16), the thickness of the gate insulating film 22 of the low-breakdown-voltage MIS transistor LVTr is the same as the thickness of the gate insulating film 21 of the stack structure and is larger than the thickness of the tunnel insulating film 2A. When the select transistor STr and the low-breakdown-voltage MIS transistor LVTr have different structures (FIG. 17), the thickness of a gate insulating film 2C is smaller than the thickness of the gate insulating film 22 and larger the thickness of the tunnel insulating film 2A.

The thickness of the gate insulating film 2D of the high-breakdown-voltage MIS transistor HVTr is larger than the thickness of the gate insulating films 2C, 22 of the low-breakdown-voltage MIS transistor LVTr.

As described above, according to the third embodiment of the present invention, the operation of the flash memory can be stable, and the manufacturing cost of the flash memory can be reduced.

### (4) Fourth Embodiment

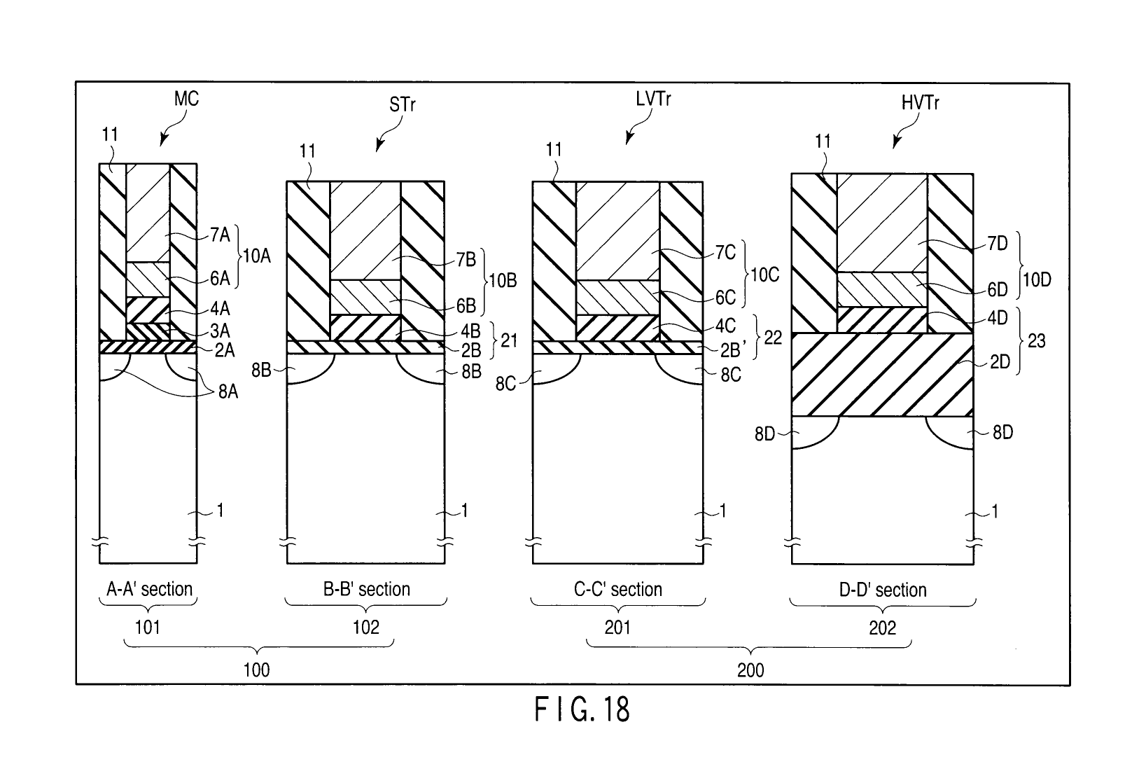

A flash memory according to a fourth embodiment of the present invention will be described with FIG. 18. It is to be noted that the same signs are assigned to parts having about the same functions as in the first to third embodiments and detailed explanations are omitted.

FIG. 18 shows the sectional structures of a memory cell MC, a select transistor STr and low-breakdown-voltage/high-breakdown-voltage MIS transistors LVTr, HVTr along the channel length direction in the flash memory according to the fourth embodiment of the present invention. It is to be noted that the structure of each element in the channel width direction has only to be the same as one of the structures shown in, for example, FIGS. 4 and 13, and is not specifically described here.

The fourth embodiment is characterized in that the low-breakdown-voltage MIS transistor LVTr and the select transistor STr have the same configuration, that a gate insulating film 23 of the high-breakdown-voltage MIS transistor HVTr includes an insulating film 4D of the same configuration as a block insulating film 4A, and that a gate electrode 10D of the high-breakdown-voltage MIS transistor HVTr has the same configuration as a gate electrode 10A of the memory cell MC.

As shown in FIG. 18, the memory cell MC has a gate structure in which a tunnel insulating film 2A, a charge storage layer 3, a block insulating film 4A and a gate electrode 10A are stacked on a semiconductor substrate 1. Further, the memory cell MC has diffusion layers 8A serving as source/drain regions in the semiconductor substrate. The gate electrode 10A has a stack structure composed of a TaN film 6A and a NiSi₂ film 7A.

The select transistor STr has a gate structure composed of a gate insulating film 21 on the surface of a semiconductor substrate 1, and a gate electrode 10B. The select transistor STr also has diffusion layers 8B serving as source/drain regions.

The gate insulating film 21 has a structure in which an insulating film 2B (e.g., a silicon oxide film) and an insulating film 4B (e.g., Al₂O₃ film) of the same configuration as the block insulating film are stacked.

Moreover, the gate structure of the low-breakdown-voltage MIS transistor LVTr is composed of a gate insulating film 22 on the surface of the semiconductor substrate 1, a gate electrode 10C on the gate insulating film 22, and diffusion layers 8C serving as source/drain regions.

The gate insulating film 22 has a stack structure composed of an insulating film 2B′ of the same configuration as the insulating film 2B constituting the gate insulating film 21 of the select transistor STr, and an insulating film 4C of the same configuration as the block insulating film 4A. The gate electrode 10C is composed of a TaN film 6C and a NiSi₂ film 7C. That is, the low-breakdown-voltage MIS transistor LVTr has about the same structure as the select transistor STr.

As shown in FIG. 18, the high-breakdown-voltage MIS transistor HVTr has a gate structure on the semiconductor substrate 1 composed of an insulating film 23 and a gate electrode 10D on the insulating film 23, and also has diffusion layers 8D serving as source/drain regions in the semiconductor substrate 1. The gate insulating film 23 has a structure in which an insulating film 2D (e.g., a silicon oxide film) and an insulating film 4D (e.g., Al₂O₃ film) of the same configuration as the block insulating film are stacked. This structure is the same as the structures of the gate insulating film 21, 22 of the select transistor STr and the low-breakdown-voltage MIS transistor LVTr.

Furthermore, the gate electrode 10D has a stack structure of a TaN film 6D and a NiSi₂ film 7D. That is, the gate electrode 10D of the high-breakdown-voltage MIS transistor HVTr has the same configuration as the gate electrodes 10A to 10C of the other elements MC, STr, LVTr.

Here, in the present embodiment, the select transistor STr and the low-breakdown-voltage MIS transistor LVTr have about the same structure, and their gate electrodes 10B, 10C have the same configuration as the gate electrode 10A of the memory cell, as described above. Moreover, the high-breakdown-voltage MIS transistor HVTr includes, in the gate insulating film 23 of its stack structure, the insulating film 4D of the same configuration as the block insulating film 4A, and the gate electrode 10D has the same configuration as the gate electrode 10A of the memory cell MC. Consequently, a plurality of conductive layers (materials) constituting the gate electrodes and a plurality of insulating films (materials) constituting the gate insulating films in the memory cell MC, the select transistor STr and the low-breakdown-voltage/high-breakdown-voltage MIS transistors LVTr, HVTr can be formed and fabricated in the simultaneous steps. Therefore, the manufacturing cost of the flash memory can be further reduced.

In addition, in the present embodiment, it is only necessary that the gate insulating film 21, 22, 23 in the stack structures of the select transistor STr and the low-breakdown-voltage/high-breakdown-voltage MIS transistor LVTr, HVTr include the insulating film 4B, 4C, 4D of the same configuration as the block insulating film 4A, and that the gate electrodes 10A, 10B, 10C, 10D of the elements MC, STr, LVTr, HVTr have the same configuration. Thus, in the structures of these gate electrodes, any other material such as a polysilicon film may be used instead of the TaN film.

Moreover, in the present embodiment, the relation of the thickness of the gate insulating films of the respective elements is as follows: The thickness of the gate insulating film 21 of the select transistor STr is preferably larger than the sum of the thickness of the tunnel oxide film 2A of the memory cell MC and the thickness of the block insulating film 4A. As the select transistor STr and the low-breakdown-voltage MIS transistor LVTr have about the same structure, the thickness of the gate insulating film 22 of the low-breakdown-voltage MIS transistor LVTr is the same as the thickness of the gate insulating film 21 of the stack structure and is larger than the thickness of the tunnel insulating film 2A. The thickness of the gate insulating film 23 of the high-breakdown-voltage MIS transistor HVTr is larger than the thickness of the gate insulating film 22 of the low-breakdown-voltage MIS transistor LVTr.

Consequently, according to the fourth embodiment of the present invention, the operation of the flash memory can be stable, and the manufacturing cost of the flash memory can be reduced.

### 3. APPLICATION

The flash memory has been described as an example of the nonvolatile semiconductor memory in the first to fourth embodiments of the present invention. In the flash memory, one of circuit configurations of, for example, a NAND type, NOR type and AND type is used for the circuit configuration of the memory cell array region 100.

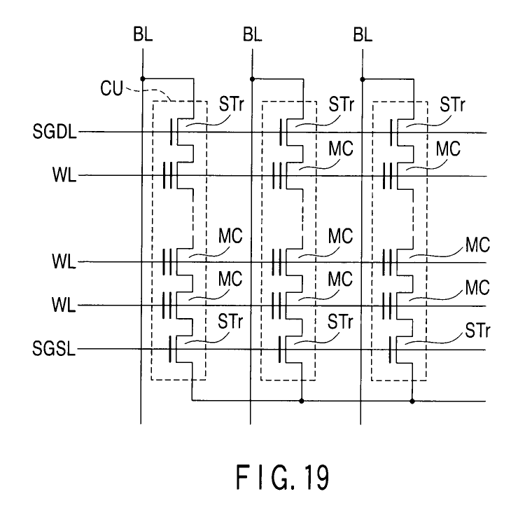

For example, as shown in FIG. 19, a memory cell array region 100 having a NAND type circuit configuration is as follows:

A plurality of memory cells having one of the structures shown in the first to fourth embodiments are provided in the memory cell array region 100 in FIG. 1. Memory cells MC adjacent to each other in the channel length direction share diffusion layers serving as source/drain regions and are connected in series. The memory cells connected in series are called a NAND string.

Select transistors STr having one of the structures shown in the first to fourth embodiments are provided on one end and the other of the NAND string, and the NAND string is connected to adjacent memory cells by the diffusion layers serving as the source/drain regions. A NAND cell unit (memory cell unit) CU is constituted by the plurality of memory cells connected in series (NAND string) and by the select transistors connected on one end and the other thereof.

A source line SL is connected to the diffusion layers in the select transistor on one end in the NAND cell unit CU, and a bit line BL is connected to the diffusion layers in the select transistor on the other end.

Furthermore, the memory cells MC adjacent in the channel width direction share a gate electrode extending in the channel width direction and are thus connected to each other. That is, the gate electrodes of the memory cells function as word lines WL. Similarly, the select transistors STr adjacent in the channel width direction share a gate electrode extending in the channel width direction and are thus connected to each other. That is, the gate electrodes of the select transistors STr function as select gate lines SGDL, SGSL.

In a peripheral circuit region 200, there are provided a low-breakdown-voltage MIS transistor LVTr and a high-breakdown-voltage MIS transistor HVTr which have one of the structures shown in the first to fourth embodiments and which drive the memory cell and the select transistors.

As described above, the flash memories shown in the first to fourth embodiments of the present invention are applicable to a flash memory having a circuit configuration of, for example, the NAND type.

### 4. OTHERS

According to the embodiments of the present invention, the operation of the nonvolatile semiconductor memory can be stable, and the manufacturing cost of the nonvolatile semiconductor memory can be reduced.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A nonvolatile semiconductor memory comprising:
a semiconductor substrate;
a memory cell array region provided in the semiconductor substrate;
a peripheral circuit region provided in the semiconductor substrate adjacently to the memory cell array region;
at least one memory cell which is provided in the memory cell array region and which has a first gate insulating film on the surface of the semiconductor substrate, a charge storage layer on the first gate insulating film, a block insulating film on the charge storage layer, and a first gate electrode on the block insulating film;
at least one first transistor which is provided in the memory cell array region and which has a second gate insulating film on the surface of the semiconductor substrate and a second gate electrode on the second gate insulating film;
at least one second transistor which is provided in the peripheral circuit region and which has a third gate insulating film on the surface of the semiconductor substrate and a third gate electrode on the third gate insulating film; and
at least one third transistor which is provided in the peripheral circuit region and which has a fourth gate insulating film on the surface of the semiconductor substrate and a fourth gate electrode on the fourth gate insulating film and which is different in drive voltage from the second transistor,
wherein the second gate insulating film includes an insulating film of the same configuration as the block insulating film,
the second gate electrode has the same structure as the first gate electrode, and
the third and fourth gate electrodes partly include conductive layers of the same configuration as the first gate electrode.

2. The nonvolatile semiconductor memory according to claim 1, wherein
the thickness of the second gate insulating film is larger than the sum of the thickness of the first gate insulating film and the thickness of the block insulating film,
the thickness of the third gate insulating film is equal to or less than the thickness of the second gate insulating film, and
the thickness of the fourth gate insulating film is larger than the thickness of the third gate insulating film.

3. The nonvolatile semiconductor memory according to claim 1, wherein
the second gate insulating film is a single-layer film made of an insulating film of the same configuration as the block insulating film.

4. The nonvolatile semiconductor memory according to claim 1, further comprising:
an isolation insulating film which divides the memory cell array region,
the upper surface of the isolation insulating film being in contact with the first gate electrode.

5. The nonvolatile semiconductor memory according to claim 1, further comprising:
an isolation insulating film which divides the memory cell array region,
the upper surface of the isolation insulating film being in contact with the block insulating film.

6. The nonvolatile semiconductor memory according to claim 1, wherein
the first gate electrode includes a under part layer and an upper part layer,
an upper part layer of the third and forth electrode has the same configuration as the first gate electrode.

7. A nonvolatile semiconductor memory comprising:
a semiconductor substrate;
a memory cell array region provided in the semiconductor substrate;
a peripheral circuit region provided in the semiconductor substrate adjacently to the memory cell array region;
at least one memory cell which is provided in the memory cell array region and which has a first gate insulating film on the surface of the semiconductor substrate, a charge storage layer on the first gate insulating film, a block insulating film on the charge storage layer, and a first gate electrode on the block insulating film;
at least one first transistor which is provided in the memory cell array region and which has a second gate insulating film on the surface of the semiconductor substrate and a second gate electrode on the second gate insulating film;
at least one second transistor which is provided in the peripheral circuit region and which has a third gate insulating film on the surface of the semiconductor substrate and a third gate electrode on the third gate insulating film; and
at least one third transistor which is provided in the peripheral circuit region and which has a fourth gate insulating film on the surface of the semiconductor substrate and a fourth gate electrode on the fourth gate insulating film and which is different in drive voltage from the second transistor,
wherein the first gate electrode has a plurality of conductive layers,
the second gate insulating film includes an insulating film of the same configuration as the block insulating film,
the second gate electrode has the same structure as the first gate electrode, and
the third and fourth gate electrodes include conductive layers of the same configuration as at least one of the plurality of conductive layers constituting the first gate electrode.

8. The nonvolatile semiconductor memory according to claim 7, wherein
the thickness of the second gate insulating film is larger than the sum of the thickness of the first gate insulating film and the thickness of the block insulating film,
the thickness of the third gate insulating film is equal to or less than the thickness of the second gate insulating film, and
the thickness of the fourth gate insulating film is larger than the thickness of the third gate insulating film.

9. The nonvolatile semiconductor memory according to claim 7, wherein
the third gate electrode has the same structure as the fourth gate electrode.

10. The nonvolatile semiconductor memory according to claim 7, further comprising:
an isolation insulating film which divides the memory cell array region,
the upper surface of the isolation insulating film being in contact with the first gate electrode.

11. The nonvolatile semiconductor memory according to claim 7, further comprising:
an isolation insulating film which divides the memory cell array region,
the upper surface of the isolation insulating film being in contact with the block insulating film.

12. The nonvolatile semiconductor memory according to claim 7, wherein
the first gate electrode includes a under part layer and an upper part layer,
an upper part layer of the third and forth electrode has the same configuration as the upper part layer of the first gate electrode.

13. A nonvolatile semiconductor memory comprising:
a semiconductor substrate;
a memory cell array region provided in the semiconductor substrate;
a peripheral circuit region provided in the semiconductor substrate adjacently to the memory cell array region;
at least one memory cell which is provided in the memory cell array region and which has a first gate insulating film on the surface of the semiconductor substrate, a charge storage layer on the first gate insulating film, a block insulating film on the charge storage layer, and a first gate electrode on the block insulating film;
at least one first transistor which is provided in the memory cell array region and which has a second gate insulating film on the surface of the semiconductor substrate and a second gate electrode on the second gate insulating film;
at least one second transistor which is provided in the peripheral circuit region and which has a third gate insulating film on the surface of the semiconductor substrate and a third gate electrode on the third gate insulating film; and
at least one third transistor which is provided in the peripheral circuit region and which has a fourth gate insulating film on the surface of the semiconductor substrate and a fourth gate electrode on the fourth gate insulating film and which is different in drive voltage from the second transistor,
wherein the second and third gate insulating films include insulating films of the same configuration as the block insulating film, and
the second and third gate electrodes have the same structure as the first gate electrode.

14. The nonvolatile semiconductor memory according to claim 13, wherein
the fourth gate insulating film partly includes an insulating film of the same configuration as the block insulating film, and
the fourth gate electrode has the same structure as the first gate electrode.

15. The nonvolatile semiconductor memory according to claim 13, wherein
the thickness of the second gate insulating film is larger than the sum of the thickness of the first gate insulating film and the thickness of the block insulating film,
the thickness of the third gate insulating film is equal to the thickness of the second gate insulating film, and
the thickness of the fourth gate insulating film is larger than the thickness of the third gate insulating film.

16. The nonvolatile semiconductor memory according to claim 13, wherein
the fourth gate electrode includes a conductive layer of the same configuration as the first gate electrode.

17. The nonvolatile semiconductor memory according to claim 13, wherein
the number of conductive layers included in the fourth gate electrode is greater than the number of conductive layers included in the first gate electrode.

18. The nonvolatile semiconductor memory according to claim 13, further comprising:
an isolation insulating film which divides the memory cell array region,
the upper surface of the isolation insulating film being in contact with the first gate electrode.

19. The nonvolatile semiconductor memory according to claim 13, further comprising:
an isolation insulating film which divides the memory cell array region,
the upper surface of the isolation insulating film being in contact with the block insulating film.

20. The nonvolatile semiconductor memory according to claim 13, wherein
the first gate electrode includes a under part layer and an upper part layer,
an upper part layer of the third and forth electrodes has the same configuration as the first gate electrode.
